(19) United States
(12) Patent Application Publication
(10) Pub. No.: US 2026/0157180 A1
(43) Pub. Date: Jun. 4, 2026

(54) SYSTEM-ON-WAFER AND METHODS OF FORMING THE SAME

(71) Applicant: Taiwan Semiconductor Manufacturing Co., Ltd., Hsinchu (TW)

(72) Inventors: Shih-Wei Chen, Hsinchu (TW); Meng-Tsan Lee, Hsinchu (TW); Chun-Yi Liu, Hsinchu (TW); Tai-You Liu, Hsinchu (TW); Po-Chang Shih, Taichung (TW); An-Jhih Su, Taoyuan (TW); Der-Chyang Yeh, Hsinchu (TW)

(21) Appl. No.: 19/181,912

(22) Filed: Apr. 17, 2025

Related U.S. Application Data
(60) Provisional application No. 63/727,432, filed on Dec. 3, 2024.

(51) Int. Cl. H01L 23/40; G02B 6/43; H01L 21/48; H01L 23/427; H01L 23/538; H01L 25/16; H01R 12/79; H10B 80/00

(52) U.S. Cl. CPC H10W 40/611; G02B 6/43; H01R 12/79; H10W 40/037; H10W 40/73; H10W 70/093; H10W 70/611; H10W 90/00; H10W 90/401; H10B 80/00; H10W 40/60

(57) ABSTRACT

A device includes an interposer, a package attached to a first side of the interposer, and a plurality of passive devices and external connectors attached to a second side of the interposer. The package includes an encapsulant and integrated circuit devices in the encapsulant. The interposer electrically connects the passive devices and external connectors to the integrated circuit devices. The external connectors are disposed outside a perimeter of the package in a top-down view.

### PRIORITY CLAIM AND CROSS-REFERENCE

This application claims the benefit of U.S. Provisional Application No. 63/727,432, filed on Dec. 3, 2024, which application is hereby incorporated herein by reference.

### BACKGROUND

The semiconductor industry has experienced rapid growth due to ongoing improvements in the integration density of a variety of electronic components (e.g., transistors, diodes, resistors, capacitors, etc.). For the most part, improvement in integration density has resulted from iterative reduction of minimum feature size, which allows more components to be integrated into a given area. As the demand for shrinking electronic devices has grown, a need for smaller and more creative packaging techniques of semiconductor dies has emerged.

### BRIEF DESCRIPTION OF THE DRAWINGS

Aspects of the present disclosure are best understood from the following detailed description when read with the accompanying figures. It is noted that, in accordance with the standard practice in the industry, various features are not drawn to scale. In fact, the dimensions of the various features may be arbitrarily increased or reduced for clarity of discussion.

FIG. 1 is a cross-sectional view of an integrated circuit die.

FIGS. 2A-2B are cross-sectional views of die stacks.

FIGS. 3-13 are views of intermediate stages in the manufacturing of a system package, in accordance with some embodiments.

FIG. 14 is a cross-sectional view of a system-on-wafer assembly, in accordance with some embodiments.

FIG. 15 is a cross-sectional view of a system-on-wafer assembly, in accordance with some embodiments.

FIG. 16 is a cross-sectional view of a system-on-wafer assembly, in accordance with some embodiments.

FIG. 17 is a cross-sectional view of a system-on-wafer assembly, in accordance with some embodiments.

FIGS. 18-23 are cross-sectional views of intermediate stages in the manufacturing of a wafer package, in accordance with some other embodiments.

FIG. 24 is a cross-sectional view of a system-on-wafer assembly, in accordance with some embodiments.

FIG. 25 is a cross-sectional view of a system-on-wafer assembly, in accordance with some embodiments.

### DETAILED DESCRIPTION

The following disclosure provides many different embodiments, or examples, for implementing different features of the invention. Specific examples of components and arrangements are described below to simplify the present disclosure. These are, of course, merely examples and are not intended to be limiting. For example, the formation of a first feature over or on a second feature in the description that follows may include embodiments in which the first and second features are formed in direct contact, and may also include embodiments in which additional features may be formed between the first and second features, such that the first and second features may not be in direct contact. In addition, the present disclosure may repeat reference numerals and/or letters in the various examples. This repetition is for the purpose of simplicity and clarity and does not in itself dictate a relationship between the various embodiments and/or configurations discussed.

Further, spatially relative terms, such as “beneath,” “below,” “lower,” “above,” “upper” and the like, may be used herein for ease of description to describe one element or feature's relationship to another element(s) or feature(s) as illustrated in the figures. The spatially relative terms are intended to encompass different orientations of the device in use or operation in addition to the orientation depicted in the figures. The apparatus may be otherwise oriented (rotated 90 degrees or at other orientations) and the spatially relative descriptors used herein may likewise be interpreted accordingly.

According to various embodiments, a system package may include a wafer package and a rigid interposer. The system package may be a full system, such as a system-on-wafer (SoW). The wafer package may include integrated circuit devices encapsulated in an encapsulant. The wafer package may be attached to the rigid interposer in the system package. Other components, such as passive devices and external connectors, may also be attached to the rigid interposer. The rigid interposer may include routing features such as optical waveguides and/or conductive traces to facilitate signal transmission between the components of the system package. The rigid interposer may be larger than the wafer package, with the outer perimeter of the rigid interposer extending beyond the outer perimeter of the wafer package in a top-down view. The rigid interposer may provide advantages in the system package. It may serve as a stable platform for integrating multiple components, and may allow for efficient routing of signals between different components of the system package. The rigidity of the interposer may help maintain the structural integrity of the system package, potentially reducing stress on the package components during processing or operation.

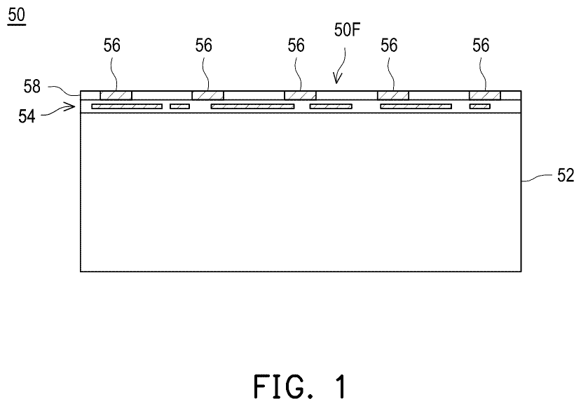

FIG. 1 is a cross-sectional view of an integrated circuit die 50. Multiple integrated circuit dies 50 will be packaged in subsequent processing. Each integrated circuit die 50 may be a logic die (e.g., central processing unit (CPU), graphics processing unit (GPU), system-on-a-chip (SoC) die, microcontroller, etc.), a memory die (e.g., dynamic random access memory (DRAM) die, static random access memory (SRAM) die, etc.), a power management die (e.g., power management integrated circuit (PMIC) die), a radio frequency (RF) die, an interface die, a sensor die, a micro-electro-mechanical-system (MEMS) die, a signal processing die (e.g., digital signal processing (DSP) die), a front-end die (e.g., analog front-end (AFE) dies), the like, or combinations thereof. The integrated circuit die 50 may be formed in a wafer, which may include different die regions that are singulated in subsequent steps to form a plurality of integrated circuit dies 50. The integrated circuit die 50 includes a semiconductor substrate 52, an interconnect structure 54, die connectors 56, and a dielectric layer 58.

The semiconductor substrate 52 may be a substrate of silicon, doped or undoped, or an active layer of a semiconductor-on-insulator (SOI) substrate. The semiconductor substrate 52 may include other semiconductor materials, such as germanium; a compound semiconductor including silicon carbide, gallium arsenide, gallium phosphide, indium phosphide, indium arsenide, and/or indium antimonide; an alloy semiconductor including silicon-germanium, gallium arsenide phosphide, aluminum indium arsenide, aluminum gallium arsenide, gallium indium arsenide, gallium indium phosphide, and/or gallium indium arsenide phosphide; or combinations thereof. Other substrates, such as multi-layered or gradient substrates, may also be used. The semiconductor substrate 52 has an active surface (e.g., the surface facing upward in FIG. 1) and an inactive surface (e.g., the surface facing downward in FIG. 1). Devices (not separately illustrated) are at the active surface of the semiconductor substrate 52. The devices may be active devices (e.g., transistors, diodes, etc.), capacitors, resistors, etc. The inactive surface may be free from devices.

The interconnect structure 54 is over the active surface of the semiconductor substrate 52, and is used to electrically connect the devices of the semiconductor substrate 52 together to form an integrated circuit. The interconnect structure 54 may include one or more dielectric layer(s) and respective metallization layer(s) in the dielectric layer(s). Acceptable dielectric materials for the dielectric layers include oxides such as silicon oxide or aluminum oxide, nitrides such as silicon nitride, combinations thereof such as silicon oxynitride, or the like. Other dielectric materials may also be used, such as polymers, such as polybenzoxazole (PBO), polyimide, a benzocyclobuten (BCB) based polymer, or the like. The metallization layer(s) may include conductive vias and/or conductive lines to interconnect the devices of the semiconductor substrate 52. The metallization layer(s) may be formed of a conductive material, such as a metal, such as copper, cobalt, aluminum, gold, combinations thereof, or the like. The metallization layer(s) of the interconnect structure 54 may be formed by a damascene process, such as a single damascene process, a dual damascene process, or the like.

Die connectors 56 are at the front-side 50F of the integrated circuit die 50. The die connectors 56 may be conductive pillars, pads, or the like, to which external connections are made. The die connectors 56 may be in and/or on the interconnect structure 54. For example, the die connectors 56 may be part of an upper metallization layer of the interconnect structure 54. The die connectors 56 may be formed of a metal, such as copper, aluminum, or the like, and may be formed by, for example, plating, or the like.

Optionally, solder regions (not separately illustrated) may be disposed on the die connectors 56 during formation of the integrated circuit die 50. The solder regions may be used to perform chip probe (CP) testing on the integrated circuit die 50. For example, the solder regions may be solder balls, solder bumps, or the like, which are used to attach a chip probe to the die connectors 56. Chip probe testing may be performed on the integrated circuit die 50 to ascertain whether the integrated circuit die 50 is a known good die (KGD). Thus, only integrated circuit dies 50, which are KGDs, undergo subsequent processing are packaged, and dies which fail the chip probe testing are not packaged. After testing, the solder regions may be removed.

A dielectric layer 58 is at the front-side 50F of the integrated circuit die 50. The dielectric layer 58 may be in and/or on the interconnect structure 54. For example, the dielectric layer 58 may be an upper dielectric layer of the interconnect structure 54. The dielectric layer 58 laterally encapsulates the die connectors 56. The dielectric layer 58 may be an oxide, a nitride, a polymer, the like, or a combination thereof, which may be formed, for example, by spin coating, lamination, chemical vapor deposition (CVD), or the like. Front-side surfaces of the die connectors 56 and the dielectric layer 58 may be substantially coplanar (within process variations) at the front-side 50F of the integrated circuit die 50.

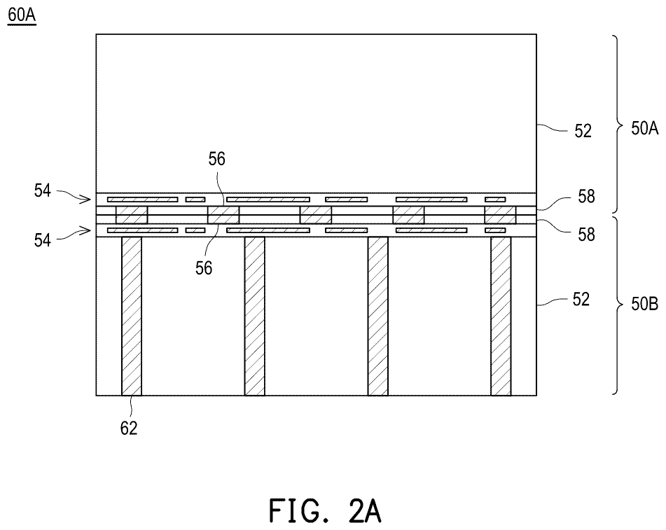

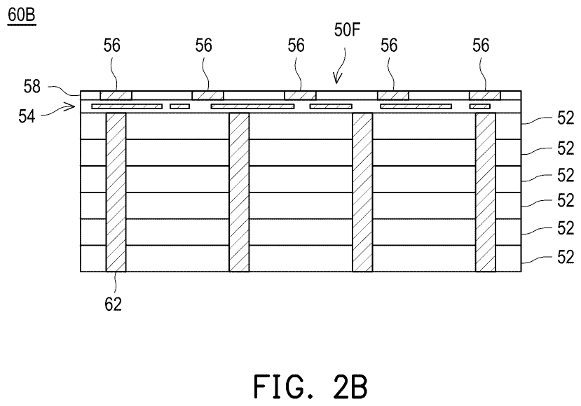

FIGS. 2A-2B are cross-sectional views of die stacks 60A, 60B, respectively. The die stacks 60A, 60B may each have a single function (e.g., a logic device, memory die, etc.), or may each have multiple functions. In some embodiments, the die stack 60A is a logic device such as a system-on-integrated-chip (SoIC) device and the die stack 60B is a memory device such as high bandwidth memory (HBM) device.

As shown in FIG. 2A, the die stack 60A includes two bonded integrated circuit dies 50 (e.g., a first integrated circuit die 50A and a second integrated circuit die 50B). In some embodiments, the first integrated circuit die 50A is a logic die and the second integrated circuit die 50B is an interface die. An interface die bridges a logic die to memory dies, and translates commands between the logic die and the memory dies. In some embodiments, the first integrated circuit die 50A and the second integrated circuit die 50B are bonded such that the active surfaces are facing each other (e.g., are “face-to-face” bonded). Conductive vias 62 may be formed through one of the integrated circuit dies 50 so that external connections may be made to the die stack 60A. The conductive vias 62 may be through-substrate vias (TSVs), such as through-silicon vias or the like. In the illustrated embodiment, the conductive vias 62 are formed in the second integrated circuit die 50B (e.g., the interface die). The conductive vias 62 extend through the semiconductor substrate 52 of the respective integrated circuit die 50, to be physically and electrically connected to the metallization layer(s) of the interconnect structure 54.

As shown in FIG. 2B, the die stack 60B is a stacked device that includes multiple semiconductor substrates 52. For example, the die stack 60B may be a stacked memory device that includes multiple memory dies such as a hybrid memory cube (HMC) device, a high bandwidth memory (HBM) cube, or the like. Each semiconductor substrate 52 may (or may not) have a separate interconnect structure 54. The semiconductor substrates 52 are connected by conductive vias 62, such as TSVs.

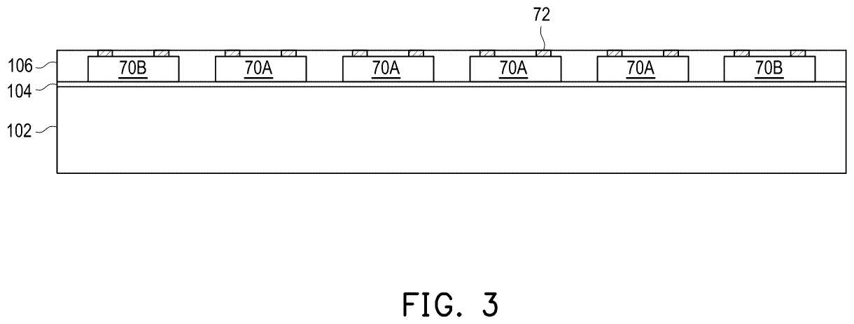

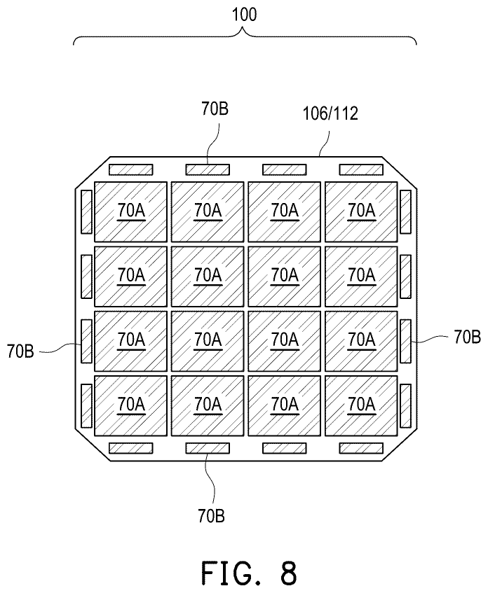

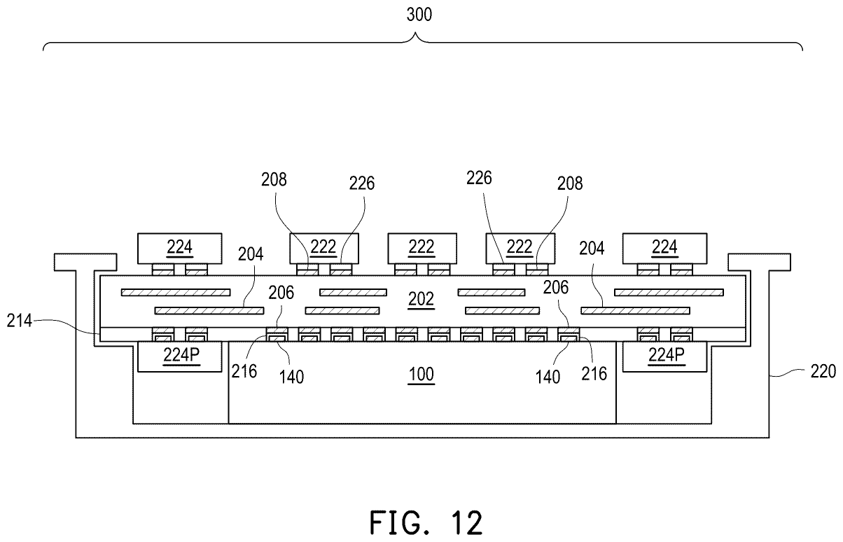

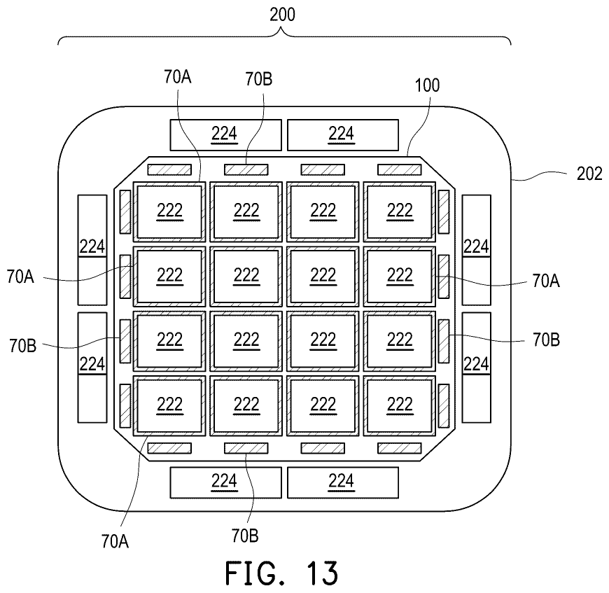

FIGS. 3-13 are views of intermediate stages in the manufacturing of a system package 200 (see FIGS. 12-13), in accordance with some embodiments. FIGS. 3-7 and 10-12 are cross-sectional views while FIGS. 8-9 and 13 are top-down views. The system package is formed by initially forming a wafer package. The wafer package is a reconstructed wafer including integrated circuit devices in an encapsulant. The wafer package is attached to a rigid interposer. Other components, such as passive devices and external connectors, may also be attached to the rigid interposer. The rigid interposer may include routing features such as optical waveguides and/or conductive traces to facilitate signal transmission between components of the system package. The rigid interposer may be larger than the wafer package, with the outer perimeter of the rigid interposer extending beyond the outer perimeter of the wafer package in a top-down view. Further, the interposer may have a greater rigidity than the wafer package. The rigidity of the interposer may help maintain the structural integrity of the system package, potentially reducing stress on the attached components.

The system package has multiple computing sites and multiple connecting sites. The computing sites may include integrated circuit devices. Each integrated circuit device may have e.g., logic functions, memory functions, or the like, and the system package may be a single computing system including the computing sites and connecting sites, such as a system-on-wafer (SoW). For example, the system package may be an artificial intelligence (AI) accelerator, and each computing site may be a neural network node for the AI accelerator. The connecting sites may include external connectors for connecting the computing sites to an external system. Example external systems that may implement the system package include AI servers, high-performance computing (HPC) systems, high power computing devices, cloud computing systems, edge computing systems, and the like.

In FIG. 3, a carrier substrate 102 is provided, and a release layer 104 is formed on the carrier substrate 102. The carrier substrate 102 may be a glass carrier substrate, a ceramic carrier substrate, or the like. The carrier substrate 102 may be a wafer.

The release layer 104 may be formed of a polymer-based material, which may be removed along with the carrier substrate 102 from the overlying structure that will be formed in subsequent steps. In some embodiments, the release layer 104 is an epoxy-based thermal-release material, which loses its adhesive property when heated, such as a light-to-heat-conversion (LTHC) release coating. In other embodiments, the release layer 104 may be an ultra-violet (UV) glue, which loses its adhesive property when exposed to UV light. The release layer 104 may be dispensed as a liquid and cured, may be a laminate film laminated onto the carrier substrate 102, or may be the like. The top surface of the release layer 104 may be leveled and may have a high degree of planarity.

Integrated circuit devices 70 are then attached to the release layer 104. A desired type and number of integrated circuit devices 70 are placed adjacent one another. In some embodiments, the integrated circuit devices 70 include a first type of integrated circuit device (such as computing devices 70A) and a second type of integrated circuit device (such as interface devices 70B). The computing devices 70A and the interface devices 70B may be formed in processes of a same technology node, or may be formed in processes of different technology nodes. For example, the computing devices 70A may be formed by a more advanced process node than the interface devices 70B.

Each computing device 70A may include a logic die, a memory die, and/or the like. The computing devices 70A may be integrated circuit dies (similar to the integrated circuit die 50 described for FIG. 1) or may be die stacks (similar to the die stacks 60A, 60B described for FIGS. 2A-2B). In some embodiments, the computing devices 70A are die stacks, such as system-on-integrated-chip (SoIC) devices. Each die stack may include a system-on-a-chip (SoC) die and one or more HBM dies.

Each interface device 70B may include input/output interfaces, memory controllers, network interfaces, or other types of interface circuitry to bridge communication between the computing devices 70A and external components. The interface devices 70B may translate commands and data between protocols used by the computing devices 70A and protocols used by the external components. The interface devices 70B may be integrated circuit dies (similar to the integrated circuit die 50 described for FIG. 1) or may be die stacks (similar to the die stacks 60A, 60B described for FIGS. 2A-2B). In some embodiments, the interface devices 70B are I/O dies.

The interface devices 70B may be arranged around the computing devices 70A to facilitate connections to external systems. In particular, the interface devices 70B may surround the computing devices 70A in a top-down view (subsequently described). This arrangement may allow for shorter electrical paths between the interface devices 70B and external connectors (subsequently described) that will be attached to the system package.

An encapsulant 106 is formed on and around the various components. After formation, the encapsulant 106 may encapsulate the integrated circuit devices 70. The encapsulant 106 may be a molding compound, epoxy, or the like, and may be applied by compression molding, transfer molding, or the like. The encapsulant 106 may be applied in liquid or semi-liquid form and then subsequently cured. In some embodiments, the encapsulant 106 is formed over the carrier substrate 102 such that the integrated circuit devices 70 are buried or covered, and a planarization process may then be performed on the encapsulant 106 to expose die connectors 72 of the integrated circuit devices 70. The planarization process may be, for example, a chemical-mechanical polish (CMP), a grinding process, or the like. The top surfaces of the encapsulant 106 and the die connectors 72 may be substantially coplanar (within process variations) after the planarization process.

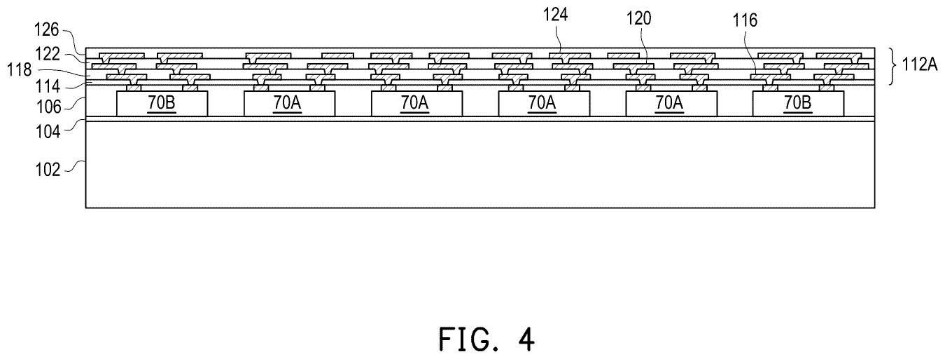

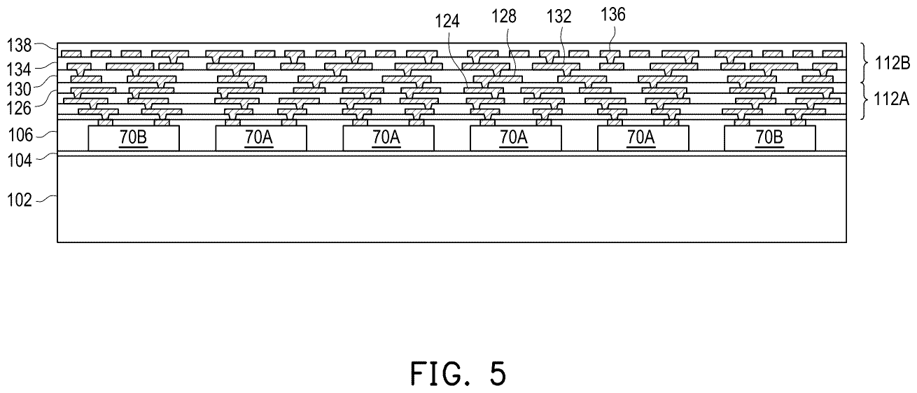

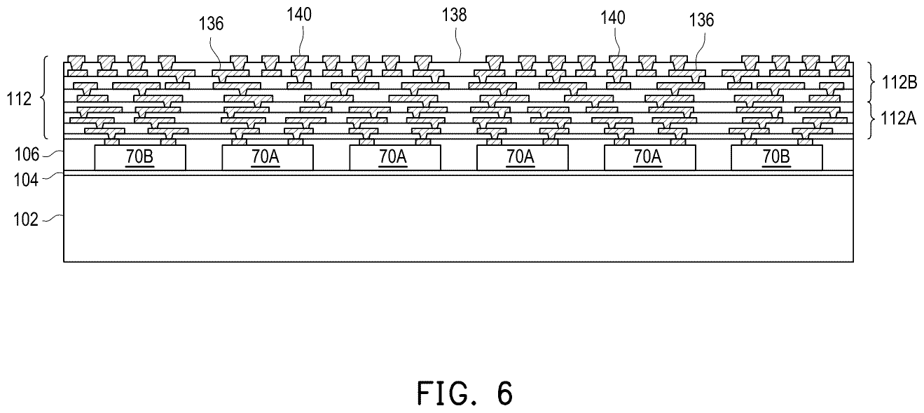

In FIGS. 4-5, a redistribution structure 112 (see FIG. 6) having a fine-featured portion 112A and a coarse-featured portion 112B is formed over the encapsulant 106 and integrated circuit devices 70. The redistribution structure 112 includes metallization patterns and dielectric layers. The metallization patterns may also be referred to as redistribution layers, redistribution lines, or traces. The fine-featured portion 112A includes metallization patterns and dielectric layers of differing sizes than the coarse-featured portion 112B. The redistribution structure 112 is shown as an example having six layers of metallization patterns. More or fewer dielectric layers and metallization patterns may be formed in the redistribution structure 112 by repeating or omitting steps and processes discussed below.

In FIG. 4, the fine-featured portion 112A of the redistribution structure 112 is formed. The fine-featured portion 112A of the redistribution structure 112 includes dielectric layers 114, 118, 122, 126 and metallization patterns 116, 120, 124. In some embodiments, the dielectric layers 118, 122, 126 are formed from a same dielectric material, and are formed to a same thickness. Likewise, in some embodiments, the conductive features of the metallization patterns 116, 120, 124 are formed from a same conductive material, and are formed to a same thickness. The dielectric layers 118, 122, 126 have a thickness that is small, and the conductive features of the metallization patterns 116, 120, 124 have a thickness that is small.

As an example of forming the fine-featured portion 112A of the redistribution structure 112, the dielectric layer 114 is deposited on the encapsulant 106 and the integrated circuit devices 70 (including the die connectors 72). In some embodiments, the dielectric layer 114 is formed of a photosensitive material such as PBO, polyimide, BCB, or the like, which may be patterned using a lithography mask. The dielectric layer 114 may be formed by spin coating, lamination, CVD, the like, or a combination thereof. The dielectric layer 114 is then patterned. The patterning forms openings exposing portions of the die connectors 72. The patterning may be by an acceptable process, such as by exposing the dielectric layer 114 to light when the dielectric layer 114 is a photosensitive material or by etching using, for example, an anisotropic etch. If the dielectric layer 114 is a photosensitive material, the dielectric layer 114 can be developed after the exposure.

The metallization pattern 116 is then formed. The metallization pattern 116 has line portions (also referred to as conductive lines) on and extending along the major surface of the dielectric layer 114, and has via portions (also referred to as conductive vias) extending through the dielectric layer 114 to physically and electrically couple the die connectors 72 of the integrated circuit devices 70. As an example to form the metallization pattern 116, a seed layer is formed over the dielectric layer 114 and in the openings extending through the dielectric layer 114. In some embodiments, the seed layer is a metal layer, which may be a single layer or a composite layer including a plurality of sub-layers formed of different materials. In some embodiments, the seed layer includes a titanium layer and a copper layer over the titanium layer. The seed layer may be formed using, for example, physical vapor deposition (PVD) or the like. A photoresist is then formed and patterned on the seed layer. The photoresist may be formed by spin coating or the like and may be exposed to light for patterning. The pattern of the photoresist corresponds to the metallization pattern 116. The patterning forms openings through the photoresist to expose the seed layer. A conductive material is then formed in the openings of the photoresist and on the exposed portions of the seed layer. The conductive material may be formed by plating, such as electroplating or electroless plating, or the like. The conductive material may include a metal, like copper, titanium, tungsten, aluminum, or the like. The combination of the conductive material and underlying portions of the seed layer form the metallization pattern 116. The photoresist and portions of the seed layer on which the conductive material is not formed are removed. The photoresist may be removed by an acceptable ashing or stripping process, such as using an oxygen plasma or the like. Once the photoresist is removed, exposed portions of the seed layer are removed, such as by using an acceptable etching process, such as by wet or dry etching.

The dielectric layer 118 is then deposited on the metallization pattern 116 and dielectric layer 114. The dielectric layer 118 may be formed in a similar manner and of a similar material as the dielectric layer 114.

The metallization pattern 120 is then formed. The metallization pattern 120 has line portions on and extending along the major surface of the dielectric layer 118, and has via portions extending through the dielectric layer 118 to physically and electrically couple the metallization pattern 116. The metallization pattern 120 may be formed in a similar manner and of a similar material as the metallization pattern 116.

The dielectric layer 122 is then deposited on the metallization pattern 120 and dielectric layer 118. The dielectric layer 122 may be formed in a similar manner and of a similar material as the dielectric layer 114.

The metallization pattern 124 is then formed. The metallization pattern 124 has line portions on and extending along the major surface of the dielectric layer 122, and has via portions extending through the dielectric layer 122 to physically and electrically couple the metallization pattern 120. The metallization pattern 124 may be formed in a similar manner and of a similar material as the metallization pattern 116.

The dielectric layer 126 is deposited on the metallization pattern 124 and dielectric layer 122. The dielectric layer 126 may be formed in a similar manner and of a similar material as the dielectric layer 114.

In FIG. 5, the coarse-featured portion 112B of the redistribution structure 112 is formed. The coarse-featured portion 112B of the redistribution structure 112 includes dielectric layers 130, 134, 138 and metallization patterns 128, 132, 136. In some embodiments, the dielectric layers 130, 134, 138 are formed from a same dielectric material, and are formed to a same thickness. Likewise, in some embodiments, the conductive features of the metallization patterns 128, 132, 136 are formed from a same conductive material, and are formed to a same thickness. The dielectric layers 130, 134, 138 have a thickness that is large, and the conductive features of the metallization patterns 128, 132, 136 have a thickness that is large. In particular, the thicknesses of the dielectric layers 130, 134, 138 are larger than the thicknesses of the dielectric layers 118, 122, 126 (see FIG. 4), and the thicknesses of the conductive features of the metallization patterns 128, 132, 136 are larger than the thicknesses of the conductive features of the metallization patterns 116, 120, 124 (see FIG. 4).

As an example of forming the coarse-featured portion 112B of the redistribution structure 112, the metallization pattern 128 is formed. The metallization pattern 128 has line portions on and extending along the major surface of the dielectric layer 126, and has via portions extending through the dielectric layer 126 to physically and electrically couple the metallization pattern 124. As an example to form the metallization pattern 128, a seed layer is formed over the dielectric layer 126 and in the openings extending through the dielectric layer 126. In some embodiments, the seed layer is a metal layer, which may be a single layer or a composite layer including a plurality of sub-layers formed of different materials. In some embodiments, the seed layer includes a titanium layer and a copper layer over the titanium layer. The seed layer may be formed using, for example, PVD or the like. A photoresist is then formed and patterned on the seed layer. The photoresist may be formed by spin coating or the like and may be exposed to light for patterning. The pattern of the photoresist corresponds to the metallization pattern 128. The patterning forms openings through the photoresist to expose the seed layer. A conductive material is then formed in the openings of the photoresist and on the exposed portions of the seed layer. The conductive material may be formed by plating, such as electroplating or electroless plating, or the like. The conductive material may include a metal, like copper, titanium, tungsten, aluminum, or the like. The combination of the conductive material and underlying portions of the seed layer form the metallization pattern 128. The photoresist and portions of the seed layer on which the conductive material is not formed are removed. The photoresist may be removed by an acceptable ashing or stripping process, such as using an oxygen plasma or the like. Once the photoresist is removed, exposed portions of the seed layer are removed, such as by using an acceptable etching process, such as by wet or dry etching.

The dielectric layer 130 is then deposited on the metallization pattern 128 and dielectric layer 126. In some embodiments, the dielectric layer 130 is formed of a photosensitive material such as PBO, polyimide, BCB, or the like, which may be patterned using a lithography mask. The dielectric layer 130 may be formed by spin coating, lamination, CVD, the like, or a combination thereof. The dielectric layer 130 is then patterned. The patterning forms openings exposing portions of the metallization pattern 128. The patterning may be by an acceptable process, such as by exposing the dielectric layer 130 to light when the dielectric layer 130 is a photosensitive material or by etching using, for example, an anisotropic etch. If the dielectric layer 130 is a photosensitive material, the dielectric layer 130 can be developed after the exposure.

The metallization pattern 132 is then formed. The metallization pattern 132 has line portions on and extending along the major surface of the dielectric layer 130, and has via portions extending through the dielectric layer 130 to physically and electrically couple the metallization pattern 128. The metallization pattern 132 may be formed in a similar manner and of a similar material as the metallization pattern 128.

The dielectric layer 134 is then deposited on the metallization pattern 132 and dielectric layer 130. The dielectric layer 134 may be formed in a similar manner and of a similar material as the dielectric layer 130.

The metallization pattern 136 is then formed. The metallization pattern 136 has line portions on and extending along the major surface of the dielectric layer 134, and has via portions extending through the dielectric layer 134 to physically and electrically couple the metallization pattern 132. The metallization pattern 136 may be formed in a similar manner and of a similar material as the metallization pattern 128.

The dielectric layer 138 is deposited on the metallization pattern 136 and dielectric layer 134. The dielectric layer 138 may be formed in a similar manner and of a similar material as the dielectric layer 130.

In FIG. 6, UBMs 140 are formed for external connection to the redistribution structure 112. The UBMs 140 have bump portions on and extending along the major surface of the dielectric layer 138, and have via portions extending through the dielectric layer 138 to physically and electrically couple the metallization pattern 136. As a result, the UBMs 140 are electrically coupled to the integrated circuit devices 70. The UBMs 140 may be formed in a similar manner and of a similar material as the metallization pattern 136. In some embodiments, the UBMs 140 have a different size than the metallization patterns of the redistribution structure 112.

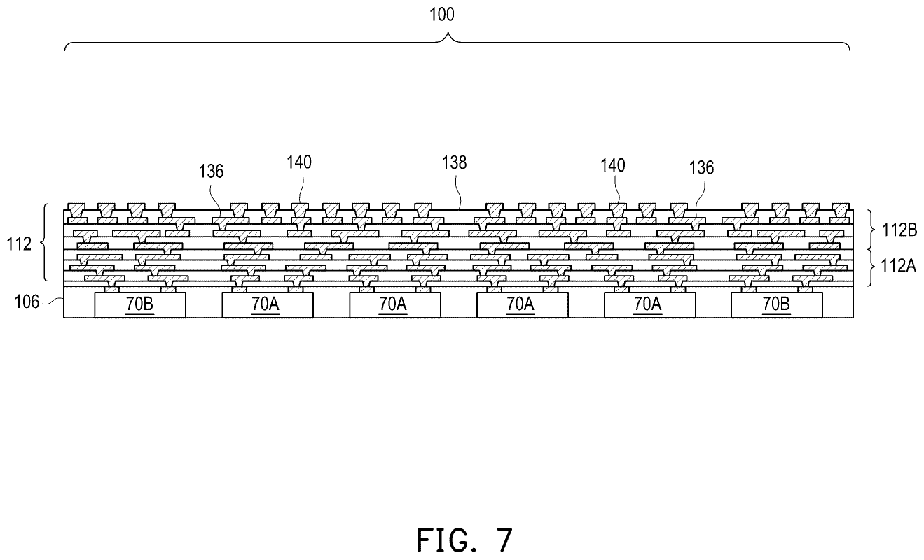

In FIG. 7, a carrier substrate de-bonding may be performed to detach (or “de-bond”) the carrier substrate 102 from the redistribution structure 112. In accordance with some embodiments, the de-bonding includes projecting a light such as a UV light on the release layer 104 so that the release layer 104 decomposes under the heat of the light and the carrier substrate 102 can be removed. The remaining structure is a wafer package 100 that will be subsequently attached to a rigid interposer. The wafer package 100 may be placed on a tape, a carrier substrate, or another suitable support structure (not separately illustrated) for subsequent processing.

Referring to FIG. 8, the integrated circuit devices 70 of the wafer package 100 are laid out in a grid pattern in a top-down view. The computing devices 70A are arranged in an array in the central region of the wafer package 100. The interface devices 70B are positioned around the perimeter of the wafer package 100, surrounding the computing devices 70A. Any desired number of interface devices 70B may be located along each edge of the wafer package 100. This arrangement allows the interface devices 70B to facilitate connections between the computing devices 70A and external components. The encapsulant 106 encompasses the integrated circuit devices 70, providing structural support and protection for the wafer package 100.

The wafer package 100 may have any desired size and shape (in the top-down view) suitable for the intended application. In this embodiment, the wafer package 100 is a truncated circular wafer, where one or more edges of the circle are flattened. In other embodiments, the wafer package 100 may be a non-truncated circular wafer. The wafer package 100 may be any size, such as about twelve inches in diameter. The specific shape and dimensions of the wafer package 100 may depend on factors such as manufacturing processes, packaging requirements, or compatibility with other system components. In some cases, a truncated circular shape may enable efficient handling during fabrication and assembly processes compared to other shaped wafers.

The computing devices 70A may be positioned in close proximity to one another within the wafer package 100. The spacing between adjacent computing devices 70A may be small, with small gaps or potentially no gaps between them. This compact arrangement may be possible due to the design of the wafer package 100, which does not need to accommodate screws or other mechanical fasteners passing through it in the final package assembly. The lack of mechanical fasteners in the wafer package 100 may be enabled by the subsequent inclusion of a rigid interposer (subsequently described) in the system package. This design approach may allow for a higher density of computing devices 70A within the wafer package 100, potentially improving overall system scale and efficiency. In some embodiments, more than eight of the computing devices 70A may be included within the wafer package 100. Additionally, the computing devices 70A and interface devices 70B may also be positioned closer together, further increasing the component density within the wafer package 100.

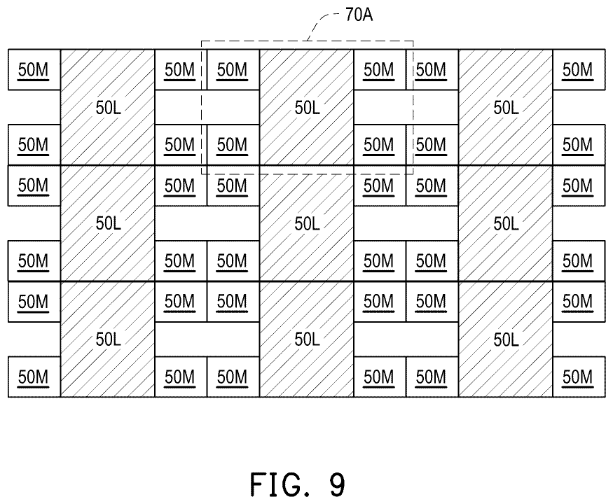

Referring to FIG. 9, the array of the computing devices 70A of the wafer package 100 is shown in more detail. Each computing device 70A may include a logic die 50L surrounded by multiple memory dies 50M. In this example, the dies have a symmetrical layout, but they may alternatively have an asymmetric layout. The memory dies 50M may be arranged along multiple sides of the logic die 50L. The configuration of dies within each computing device 70A may increase space utilization and interconnection efficiency. It is noted that the computing devices 70A may have various other die configurations depending on the specific requirements of the system, potentially including different numbers, sizes, or arrangements of logic and memory dies.

On account of the lack of mechanical fasteners in the wafer package 100, the computing devices 70A may be positioned close, potentially such that they are touching one another within the wafer package 100. This arrangement may allow for an even higher density of components compared to configurations with small gaps between computing devices 70A. In some embodiments, logic dies 50L that are adjacent to each other in one direction (e.g., the vertical direction of FIG. 9) may be in physical contact, while memory dies 50M that are adjacent to each other in another direction (e.g., the horizontal direction of FIG. 9) may be in physical contact.

Other features and processes may also be included. For example, testing structures may be included to aid in the verification testing of the 3D packaging or 3DIC devices. The testing structures may include, for example, test pads formed in a redistribution layer or on a substrate that allows the testing of the 3D packaging or 3DIC, the use of probes and/or probe cards, and the like. The verification testing may be performed on intermediate structures as well as the final structure. Additionally, the structures and methods disclosed herein may be used in conjunction with testing methodologies that incorporate intermediate verification of known good dies to increase the yield and decrease costs.

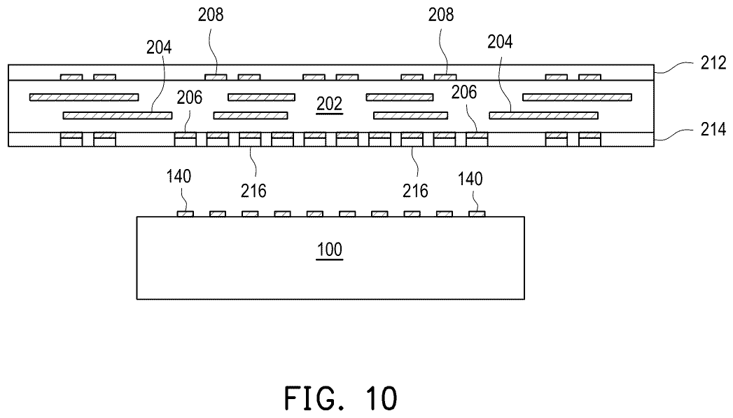

In FIG. 10, a rigid interposer 202 is received or formed. The previously formed wafer package 100 will be attached to the rigid interposer 202. This rigid interposer 202 may be obtained or formed beforehand through suitable manufacturing processes. The preparation of the rigid interposer 202 prior to its incorporation into the system package allows for efficient assembly and integration of the package components. Specifically, its rigidity enables it to support itself during processing while components such the wafer package 100 are attached thereto.

The rigid interposer 202 may have rigid properties, contributing to the structural integrity of the resulting system package. It may be constructed from rigid dielectric materials which have high stiffness and resistance to deformation under stress, such as dielectric materials having a Young's modulus of at least 10 GPa. Examples of rigid dielectric materials include glass, ceramic, undoped silicon, alumina, aluminum nitride, beryllium oxide, boron nitride, and the like. In some embodiments, the rigid interposer 202 is formed of glass. The use of such materials can provide mechanical stability, thermal management benefits, and electrical insulation properties that may be advantageous for the overall performance and reliability of the system package.

The rigid interposer 202 includes routing features 204 for signal routing. The routing features 204 may include optical routing features (e.g., optical waveguides, fiber optic cables, etc.) and/or electrical routing features (e.g., conductive lines, conductive vias, etc.). The exact type of routing features 204 utilized may depend on the specific requirements of the system package. The inclusion of these features enables complex signal pathways and interconnections between different components of the system package (e.g., integrated circuit devices of the wafer package 100, subsequently attached passive devices, subsequently attached external connectors, etc.), facilitating efficient data transfer and communication.

The rigid interposer 202 is large. Specifically, it is larger than the wafer package 100. The outer perimeter of the rigid interposer 202 will extend beyond the outer perimeter of the wafer package 100 the resulting system package. In other words, the width of the rigid interposer 202 may be greater than the width of the wafer package 100 in a cross-sectional view. The larger size of the rigid interposer 202 relative to the wafer package 100 may allow for additional routing features and external connections to be incorporated around the periphery of the wafer package 100, including those which would overhang the edge of the wafer package 100 if they were directly attached thereto. In some embodiments, the rigid interposer 202 may be a circular wafer (truncated or non-truncated) with dimensions exceeding about twelve inches in size. This large form factor can allow for the integration of numerous components and features using a single interposer that is large and rigid enough to mechanically support the resulting system package.

The rigid interposer 202 includes conductive bumps 206, 208 at each side. In particular, the rigid interposer 202 includes conductive bumps 206 on one side and conductive bumps 208 on the opposite side. These conductive bumps 206, 208 may serve as connection points for other components within the system package. In some embodiments, the wafer package 100 will be attached to the conductive bumps 206, while passive devices and/or external connectors (subsequently described) will be attached to the conductive bumps 208. The inclusion of conductive bumps 206, 208 at both sides of the rigid interposer 202 enables vertical integration and electrical connections throughout the three-dimensional structure of the system package.

A tape 212 is initially provided on the side of the rigid interposer 202 that features the conductive bumps 208. The tape 212 may support the rigid interposer 202 during initial stages of its processing, such as while attaching the wafer package 100 to the rigid interposer 202 (subsequently described). It may provide protection for the conductive bumps 208, assist in handling the rigid interposer 202, or facilitate certain manufacturing steps in the overall package production process.

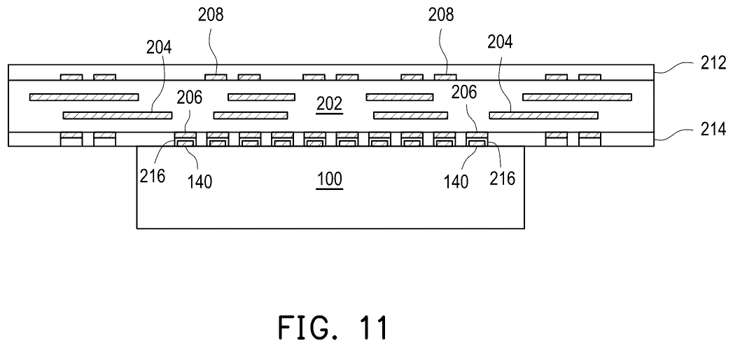

Attaching the wafer package 100 to the side of the rigid interposer 202 may include multiple steps, as will be described for FIGS. 10 and 11. The wafer package 100 may be attached to the side of the rigid interposer 202 using an adhesive layer 214 and a plurality of reflowable connectors 216. In some embodiments, the adhesive layer 214 may be used to attach the rigid interposer 202 to dielectric features of the wafer package 100, such as the top dielectric layer 138 (see FIG. 7) of the wafer's redistribution structure. The reflowable connectors 216 may be used to connect the UBMs 140 of the wafer package 100 to the conductive bumps 206 of the rigid interposer 202. This attachment method using both adhesive and reflowable connectors may provide secure mechanical and electrical connections between the wafer package 100 and the rigid interposer 202.

The adhesive layer 214 may be a bonding material used to attach the wafer package 100 to the rigid interposer 202. The adhesive layer 214 may be applied over a surface of the rigid interposer 202 to facilitate the attachment of components including the wafer package 100. In some embodiments, the adhesive layer 214 may be a B-stage adhesive film, such as a partially cured thermoset resin. B-stage adhesives are initially soft and tacky, allowing for easy application and positioning. They can then be fully cured with heat and/or pressure to create a strong bond between the wafer package 100 and rigid interposer 202. The B-stage curing process typically involves two stages: an initial partial cure to create a stable, handleable film, followed by a final cure during assembly to form the permanent bond. Some B-stage adhesives may be formed using epoxy, acrylic, or silicone chemistries. The adhesive layer 214 may also be a die attach film (DAF) or other suitable adhesive material. The adhesive layer 214 may have dielectric properties, allowing it to provide electrical insulation and reduce the risk of bridging between the conductive bumps 206.

The reflowable connectors 216 may be solder balls, metal pillars, controlled-collapse chip connection (C4) bumps, or the like. The reflowable connectors 216 may include a conductive material such as solder, copper, aluminum, gold, nickel, silver, tin, or a combination thereof. In some embodiments, the reflowable connectors 216 are formed by initially forming a layer of solder through evaporation, electroplating, printing, solder transfer, or ball placement. Once a layer of solder has been formed, a reflow may be performed in order to shape the material into the desired shapes.

The reflowable connectors 216 may be formed by first patterning the adhesive layer 214 with openings. The openings in the adhesive layer 214 may be formed using photolithography techniques, where a photoresist is applied, exposed, and developed to create a pattern. The openings may then be etched into the adhesive layer 214 using wet or dry etching processes. Once the openings are formed, the conductive material for the reflowable connectors 216 may be formed in these openings using a suitable one of the aforementioned methods. The structure may then undergo a reflow process, where heat is applied to melt and reshape the conductive material, forming the final shape of the reflowable connectors 216. This process allows for precise positioning and formation of the reflowable connectors 216 within the adhesive layer 214.

In FIG. 11, the UBMs 140 of the wafer package 100 are connected to the conductive bumps 206 of the rigid interposer 202 using the reflowable connectors 216, thereby completing the attaching of the wafer package 100 to the rigid interposer 202. Thus, the reflowable connectors 216 provide electrical connections between the wafer package 100 and rigid interposer 202. Furthermore, the adhesive layer 214 may provide mechanical connection between the wafer package 100 and rigid interposer 202.

The UBMs 140 may be connected to the conductive bumps 206 using suitable bonding techniques, such as eutectic bonding. In some embodiments, the reflowable connectors 216 may be heated until they reach a molten state. The UBMs 140 of the wafer package 100 may then be inserted into the molten reflowable connectors 216. That is, each UBM 140 may be inserted into a corresponding molten reflowable connector 216. Meanwhile, the top dielectric layer of the wafer package 100 may be pressed against the adhesive layer 214. As the reflowable connectors 216 cool and solidify, bonds may be formed between the UBMs 140 and the conductive bumps 206. This bonding process may result in the UBMs 140 extending partially into the reflowable connectors 216, creating an electrical and mechanical connection.

The spacing and alignment of the conductive bumps 206 may impact the assembly of the rigid interposer 202 and the wafer package 100. In some embodiments, the conductive bumps 206 on the rigid interposer 202 may be arranged with a pitch in the range of 500 μm to 950 μm, such as about 800 μm. This pitch may allow for sufficient spacing between adjacent conductive bumps 206 while maintaining a desired connection density. During the bonding process of the wafer package 100 to the rigid interposer 202, bonding shift may occur. In some embodiments, the bonding shift may be in the range of 50 μm to 200 μm, such as about 100 μm. This shift may be due to various factors such as thermal expansion, mechanical stress, or alignment tolerances during the attachment process.

After the wafer package 100 is attached to the rigid interposer 202, the tape 212 may be removed to expose the conductive bumps 208 on the opposite side of the rigid interposer 202. The removal of the tape 212 may prepare the exposed conductive bumps 208 for subsequent attachment of additional components to the rigid interposer 202.

In FIG. 12, passive devices 222 and external connectors 224 are attached to the side of the rigid interposer 202 opposite the wafer package 100. These components may allow for efficient power distribution and external connectivity to the resulting system package. The placement of these components on the opposite side of the rigid interposer 202 from the wafer package 100 may facilitate easier system maintenance or upgrades.

The passive devices 222 may include passive components such as capacitors, resistors, inductors, the like, or a combination thereof. The passive devices 222 may be substantially free of active devices. The passive devices 222 may be used for filtering, energy storage, impedance matching, power management, and the like. In some embodiments, a passive device 222 is a module containing multiple passive components, potentially arranged on a substrate such as a circuit board or the like. Alternatively or in addition to the passive devices 222, other types of devices may be attached to the side of the rigid interposer 202 opposite the wafer package 100. In some embodiments, optical devices, memory devices, or other types of integrated circuit devices may be attached to the rigid interposer 202. These other devices may include active devices.

In some embodiments, the passive devices 222 may be voltage regulators. The voltage regulators may be power management devices for maintaining stable voltage levels for the various components in the wafer package 100. These regulators may be implemented in various forms, such as integrated circuit dies, discrete components on circuit boards, multi-chip modules, or the like. The voltage regulators may also be implemented as switching regulators, linear regulators, or a combination of both, depending on the specific power requirements of the system. Other types of passive devices may be utilized, alternatively to or in addition to voltage regulators. In some embodiments, the passive devices 222 may be system-in-package (SiP) devices that incorporate multiple functions, including power regulation, current sensing, and thermal management.

The external connectors 224 may serve as interfaces for connecting the components of the system (e.g., the wafer package 100) to external systems or components. These connectors may be implemented as ribbon cable receptors, flexible printed circuit receptors, or other types of high-density interconnects. In some embodiments, the external connectors 224 may support various communication protocols, such as PCI-Express, USB, InfiniBand, custom high-speed interfaces, or the like. The design of these connectors may allow for easy attachment and detachment of external cables or modules, facilitating integration of the resulting system package with an external system.

The passive devices 222 and external connectors 224 may be attached to the rigid interposer 202 using reflowable connectors 226, which connect the components to the conductive bumps 208 on the rigid interposer 202. The reflowable connectors 226 may be formed of a conductive material such as solder, copper, aluminum, gold, nickel, silver, tin, or combinations thereof. In some embodiments, the reflowable connectors 226 may be solder balls, metal pillars, controlled-collapse chip connection (C4) bumps, or the like. The reflowable connectors 226 may be formed by initially forming a conductive material through methods such as evaporation, electroplating, printing, solder transfer, or ball placement. After forming the conductive material, a reflow process may be performed to shape the material into the desired connector structures.

Attaching the passive devices 222 and external connectors 224 to the rigid interposer 202 may involve placing the components on the rigid interposer 202 (e.g., conductive bumps 208) using a pick-and-place technique, followed by a reflow process to create reliable electrical and mechanical connections with the conductive bumps 208. In some embodiments, a jig 220 may be used to facilitate the attachment process. The jig 220 may include adjustable portions that can be positioned to support the rigid interposer 202 and attached components during placement and reflow. The jig 220 may also incorporate features to reduce warpage and ensure proper alignment of the components with the conductive bumps 208 on the rigid interposer 202. In some embodiments, the jig 220 may include a bottom portion for supporting the rigid interposer 202 and wafer package 100, a top portion with an opening exposing the rigid interposer 202, and a middle portion between the top and bottom portions. The middle portion of the jig 220 may be adjustable using magnetic fields to fine-tune its position. This adjustability allows the jig 220 to accommodate slight variations in component thicknesses or surface irregularities, helping to maintain consistent contact pressure across the rigid interposer 202 during the attaching of the passive devices 222 and external connectors 224.

After the passive devices 222 and external connectors 224 are attached, the jig 220 may be removed. The remaining structure is a system package 200, which may be a SoW. The SoW is a complete computing system that includes computing sites (including the computing devices of the wafer package 100 and associated passive devices 222) and connecting sites (including the interface devices of the wafer package 100 and associated external connectors 224).

Optionally, external connectors 224P may be attached to the same side of the rigid interposer 202 as the wafer package 100. In some embodiments, when the system package 200 is used for silicon photonic applications, some of the external connectors 224P (or additional connectors) may be attached to the bottom side of the rigid interposer 202. The external connectors 224P may be optical dies that perform optical signal processing, transmission, or reception. For example, the optical dies may include components such as lasers, photodetectors, modulators, or waveguides to enable optical communication capabilities. In some embodiments, the external connectors 224P are optically coupled to the wafer package 100 without the routing features 204 of the rigid interposer 202 interposed therebetween. For example, the system package 200 may include an optical pathway (such as a fiber optic cable or a waveguide, not separately illustrated) between a sidewall of an external connector 224P and a sidewall of the wafer package 100. Such an arrangement may facilitate direct optical connections between the components within the system package 200.

The external connectors 224P may be attached to some of the conductive bumps 206 on the side of the rigid interposer 202 facing the wafer package 100. This attachment process may involve using reflowable connectors similar to those used for attaching the wafer package 100 to the rigid interposer 202. Thus, in some embodiments, a first subset of conductive bumps 206 are attached to the wafer package 100 while a second subset of conductive bumps 206 are attached to the external connectors 224P. In some embodiments, a jig or fixture may be employed to support the rigid interposer 202 and ensure proper alignment of the external connectors 224P during the attachment process.

Referring to FIG. 13, the system package 200 is shown in more detail. While all of the discussed components are shown in FIG. 13 for illustration clarity, it should be appreciated that the wafer package 100 may be positioned below the rigid interposer 202 (e.g., going into the page), and the passive devices 222 and external connectors 224 may be positioned above the wafer package 100 (e.g., coming out of the page).

The passive devices 222 may be positioned directly over the computing devices 70A of the wafer package 100, with each passive device 222 corresponding to a specific computing device 70A below it. This one-to-one alignment may allow for efficient power delivery and regulation for each individual computing device 70A. Each passive device 222 may provide power for its corresponding computing device 70A through the routing features in the rigid interposer 202. Positioning the passive devices 222 close to their corresponding computing devices 70A may reduce power loss and/or voltage drops.

The external connectors 224 may be located at the periphery of the rigid interposer 202, positioned along its edges. This placement may facilitate easier connections to external components or systems, as the external connectors 224 are readily accessible at the outer boundaries of the system package 200.

The interface devices 70B are situated at the edge of the wafer package 100, potentially in close proximity to the external connectors 224. In the top-down view, the interface devices 70B are positioned between the external connectors 224 and the array of passive devices 222 and computing devices 70A. The interface devices 70B may be positioned to reduce signal path lengths between the external connectors 224 and the computing devices 70A. The interface devices 70B may mediate communications between the external connectors 224 and the internal computing devices 70A, performing signal routing and data transfer within the system package 200.

The layout of components within the system package 200 may be arranged with respect to the perimeter of the wafer package 100, in the top-down view. The passive devices 222 may be positioned within the perimeter of the wafer package 100. Meanwhile, the external connectors 224 and 224P may be positioned outside the perimeter of the wafer package 100. Other variations are possible. In some cases, the external connectors 224 and passive devices 222 can be placed on the rigid interposer 202 with more relaxed constraints, on account of the interposer's large size.

In this embodiment, both the rigid interposer 202 and the wafer package 100 are truncated circular wafers. The rigid interposer 202 may have a different shape, in the top-down view, than the wafer package 100. For example, the rigid interposer 202 may be a non-truncated circular wafer while the wafer package 100 may be a truncated circular wafer.

Furthermore, in the example of FIG. 13, the components of the system package 200 are symmetrically laid out. In another embodiment, an asymmetrical layout may be utilized. The layout of the system package 200 may be determined based on specific application needs.

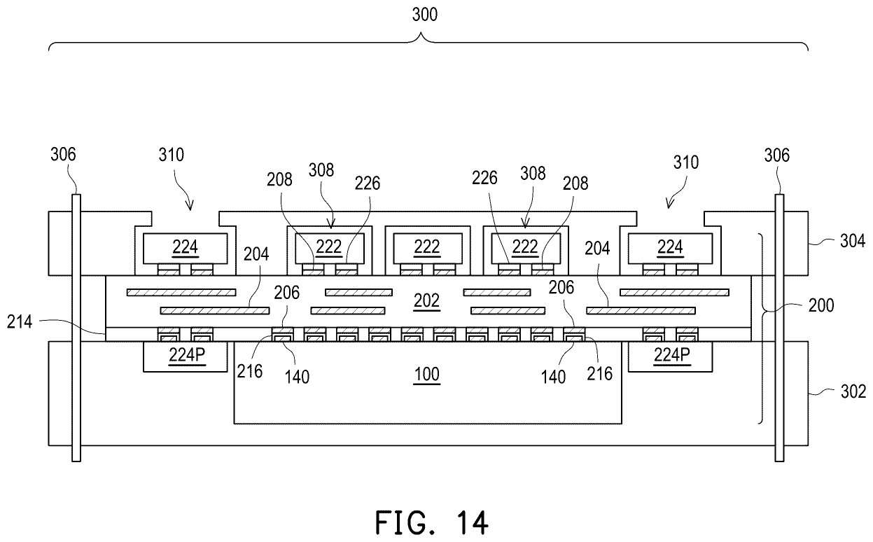

FIG. 14 is a cross-sectional view of a system-on-wafer assembly 300, in accordance with some embodiments. The system-on-wafer assembly 300 is formed by securing the system package 200 between a thermal module 302 and a frame 304. Warpage of the system package 200 may be reduced by securing the system package 200 between the thermal module 302 and the frame 304.

The thermal module 302 may be attached to the bottom of the system package 200, at the same side as the wafer package 100. The thermal module 302 is in thermal contact with the wafer package 100. The thermal module 302 may be a heat sink, heat spreader, cold plate, or similar device designed to manage heat dissipation from the components within the system-on-wafer assembly 300. The thermal module 302 physically engages portions of the adhesive layer 214. In some embodiments, the thermal module 302 may have recesses to accommodate the wafer package 100 and external connectors 224P (if present). The recesses may allow the thermal module 302 to make closer contact with heat-generating components while providing space for other protruding elements.

The frame 304 is attached to the top of the system package 200, providing structural support and protection for the internal components, such as the external connectors 224 and passive devices 222. The frame 304 is a rigid support that may be formed from a material with a high stiffness, such as a metal, e.g., steel, titanium, cobalt, or the like. In some embodiments, the system-on-wafer assembly 300 may include a spacer (not separately illustrated) between the frame 304 and the rigid interposer 202. The frame 304 (or spacer, if present) physically engages portions of the rigid interposer 202. The frame 304 has recesses 308 that accommodate the passive devices 222 and external connectors 224 at this side of the rigid interposer 202. The frame 304 also has openings 310 that may accommodate connectors (e.g., wires, cables, etc.) from external systems to the external connectors 224.

Bolts 306 may be used to fasten the system package 200 between the thermal module 302 and the frame 304. The bolts 306 may extend into or through the thermal module 302 and/or the frame 304. In particular, the thermal module 302 and the frame 304 may include corresponding bolt holes, which may be threaded or unthreaded. When the bolt holes are threaded, the bolts 306 may be directly screwed into the threaded holes. When the bolt holes are unthreaded, the bolts 306 may be secured with fasteners (not separately illustrated) such as nuts, washers, or the like. The bolts 306 secure the components of the system-on-wafer assembly 300 together, providing structural integrity and proper alignment of the various layers. The bolts 306 (or fasteners thereon) may be tightened to a specific torque to apply a desired clamping force across the system-on-wafer assembly 300.

In some embodiments, the frame 304 is first attached to the rigid interposer 202. The frame-interposer component may then be fastened to the thermal module 302 with the bolts 306. In some embodiments, other manufacturing steps could be used to assemble the components. For example, the thermal module 302 may be attached to the rigid interposer 202 before the frame 304. Alternatively, the frame 304 and thermal module 302 may be attached to the rigid interposer 202 simultaneously in certain implementations. The specific assembly sequence may depend on factors such as the materials used, thermal considerations, and manufacturing equipment available.

In some embodiments, a thermal interface material (not separately illustrated) may be applied between the thermal module 302 and the wafer package 100. The thermal interface material enhances thermal conductivity between the components and the thermal module 302, improving overall heat dissipation from the system-on-wafer assembly 300. The thermal interface material may be a film including materials such as indium or other thermally conductive substances.

Other variations are contemplated. For example, the bolts 306 may be omitted. In some embodiments, the thermal module 302 and frame 304 may instead be directly attached to sides of the rigid interposer 202. This direct attachment maybe accomplished using screws that extend into the rigid interposer 202. Alternatively, an adhesive may be used to bond the thermal module 302 and frame 304 to the rigid interposer 202. In some embodiments, a combination of screws and adhesive may provide both mechanical fastening and sealing. The specific attachment method may depend on factors such as the materials used, thermal considerations, and assembly requirements of the system-on-wafer assembly 300.

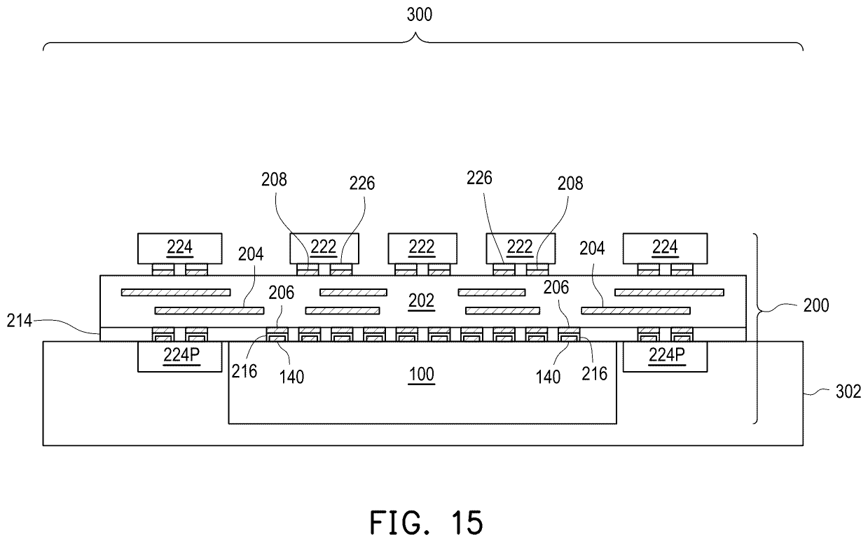

FIG. 15 is a cross-sectional view of a system-on-wafer assembly 300, in accordance with some other embodiments. This embodiment is similar to the embodiment of FIG. 14, except the frame 304 and bolts 306 are omitted. The frame 304 may be omitted since the passive devices 222 and external connectors 224 are attached to the rigid interposer 202 rather than directly to the wafer package 100. Depending on its construction, the rigid interposer 202 may provide sufficient structural support and protection for the wafer package 100 without needing an additional frame. This may allow for a more compact overall assembly design in some cases. The thermal module 302 may remain in place to manage heat dissipation from the components of the system-on-wafer assembly 300.

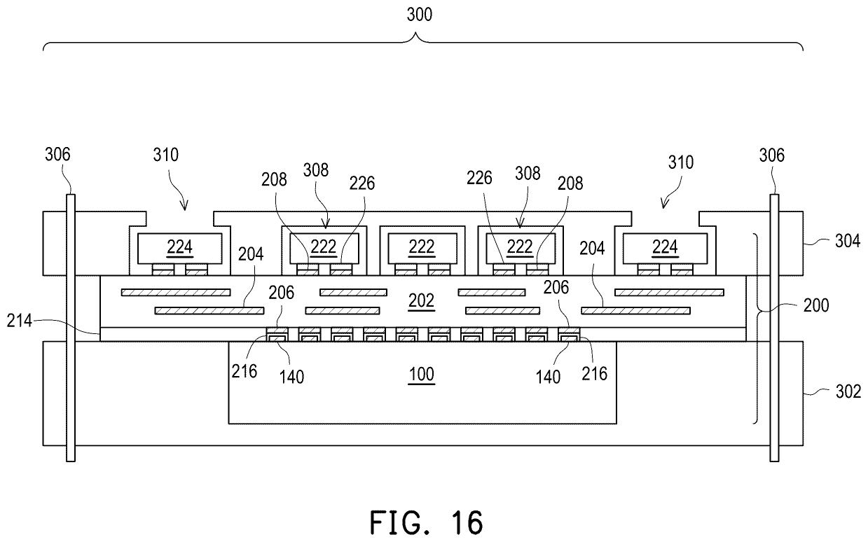

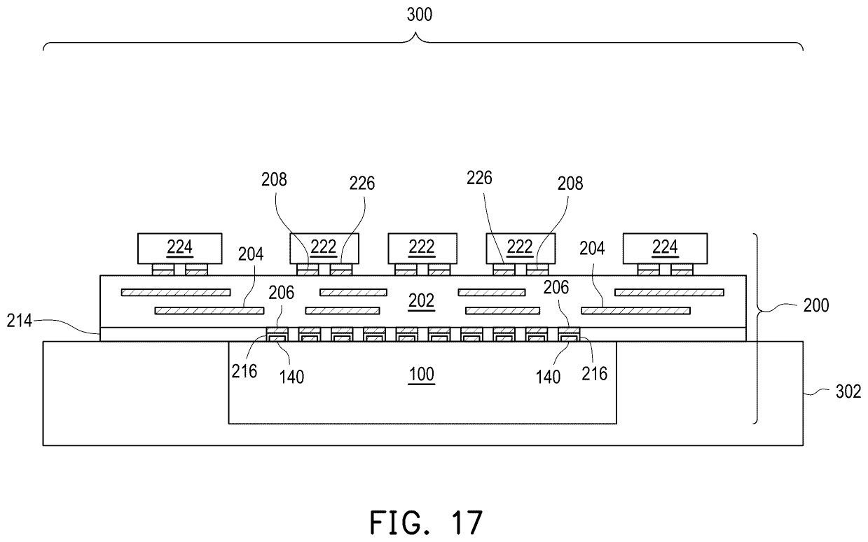

FIGS. 16-17 are cross-sectional views of system-on-wafer assemblies 300, in accordance with some other embodiments. These embodiments are similar to the embodiments of FIGS. 14-15, respectively, except the external connectors 224P are omitted. Omitting the external connectors 224P may simplify the manufacturing process, reduce costs, and/or allow for a more compact design.

Embodiments may achieve advantages. The rigid interposer 202 may serve as a stable platform for integrating multiple components in the system package 200, including the wafer package 100, passive devices 222, and external connectors 224. The rigidity of the rigid interposer 202 may help maintain the structural integrity of the system package 200. The large size of the rigid interposer 202 relative to the wafer package 100 may allow for additional routing features and external connectors 224 to be incorporated around the periphery of the system package 200. The rigid interposer 202 may include routing features 204 such as optical waveguides and/or conductive traces to facilitate efficient signal transmission between different components of the system package 200. Overall, utilizing the rigid interposer 202 in the system package 200 may enable high-performance computing capabilities in a dense form factor suitable for applications such as artificial intelligence accelerators, high-bandwidth memory systems, or the like.

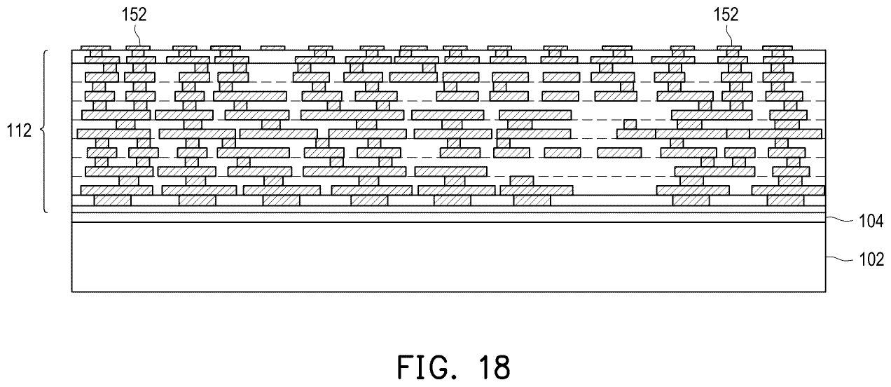

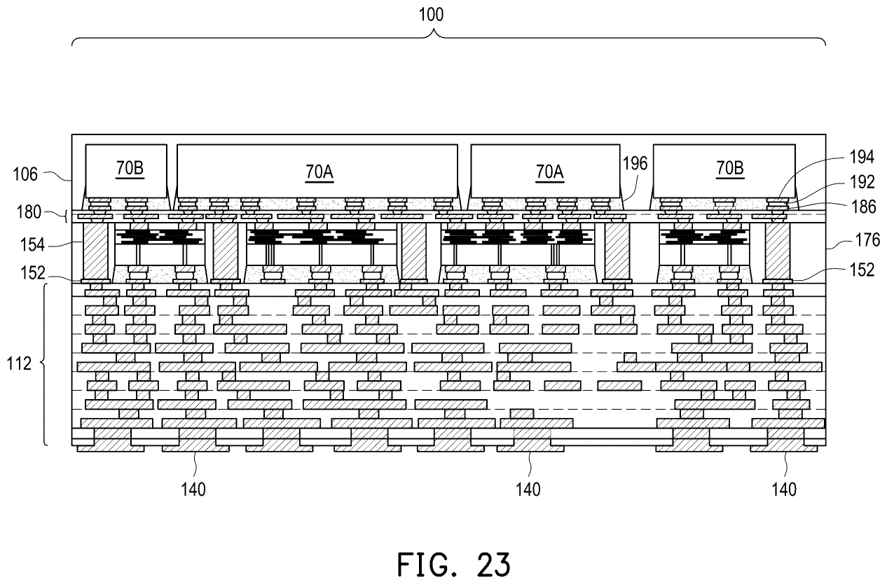

FIGS. 18-23 are cross-sectional views of intermediate stages in the manufacturing of a wafer package 100 (see FIG. 23), in accordance with some other embodiments. This wafer package 100 may also be utilized in any of the aforementioned system packages 200.

In FIG. 18, a carrier substrate 102 is provided, and a release layer 104 is formed on the carrier substrate 102. A back-side redistribution structure 112 is formed on the release layer 104. The back-side redistribution structure 112 may be formed in a similar manner as previously described for FIGS. 4-5, except it may be built up on the carrier substrate 102.

Under-bump metallization layers (UBMLs) 152 are formed for subsequent connection to the back-side redistribution structure 112. The UBMLs 152 have bump portions on and extending along the major surface of the upper dielectric layer of the back-side redistribution structure 112, and have via portions extending through the upper dielectric layer of the back-side redistribution structure 112 to physically and electrically couple the upper metallization layer of the back-side redistribution structure 112. The UBMLs 152 may be formed of the same material as the metallization layers, and may be formed by a similar process as the metallization layers. In some embodiments, the UBMLs 152 have a different size than the metallization layers.

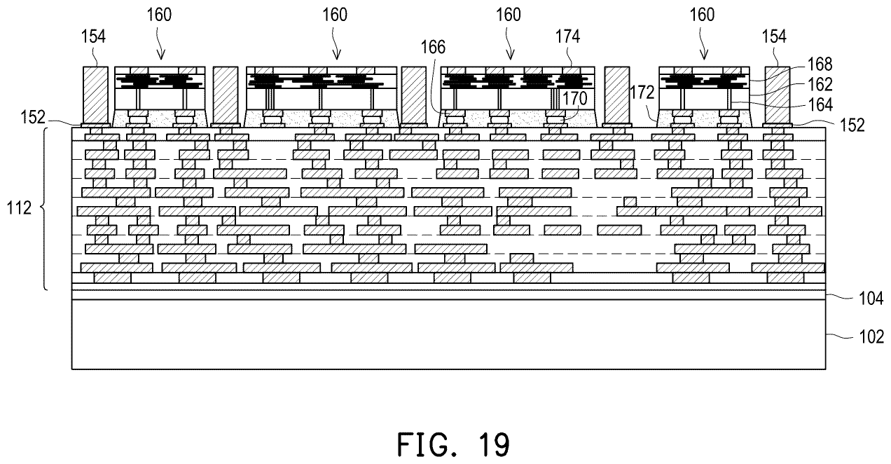

In FIG. 19, through vias 154 are formed on a first subset of the UBMLs 152. Additionally, interconnection dies 160 are attached to a second subset of the UBMLs 152. The second subset of the UBMLs 152 remain free of the through vias 154. The first subset of the UBMLs 152 and the through vias 154 will be subsequently utilized for connection to higher layers of the wafer package. The second subset of the UBMLs 152 and the interconnection dies 160 will be subsequently utilized for direct communication between integrated circuit devices of the resulting wafer package.

As an example to form the through vias 154, a photoresist is formed and patterned on the UBMLs 152 and the back-side redistribution structure 112. The photoresist may be formed by spin coating or the like and may be exposed to light for patterning. The pattern of the photoresist corresponds to the through vias 154. The patterning forms openings through the photoresist to expose the UBMLs 152. A conductive material is formed in the openings of the photoresist and on the exposed portions of the UBMLs 152. The conductive material may be formed by plating, such as electroplating or electroless plating, or the like. The conductive material of the through vias 154 may be directly plated from a conductive material of the UBMLs 152. The conductive material may include a metal, like copper, titanium, tungsten, aluminum, or the like. The photoresist is then removed. The photoresist may be removed by an acceptable ashing or stripping process, such as using an oxygen plasma or the like. The remaining portions of the conductive material form the through vias 154.

Each interconnection die 160 may be a local silicon interconnect (LSI), a large scale integration package, an interposer die, or the like. Each interconnection die 160 includes a substrate 162, with conductive features formed in and/or on the substrate 162. The substrates 162 may include a semiconductor substrate, one or more dielectric layer(s), or the like. Additionally, each interconnection die 160 may include through-substrate vias (TSVs) 164 that extend into or through the substrate 162, and may be coupled to the conductive features of the interconnection die 160. An interconnection die 160 is attached to the UBMLs 152 using die connectors 166 disposed at the back-side of the interconnection die 160. Some of the die connectors 166 may be electrically coupled to the front-side of the interconnection die 160 by the TSVs 164. As subsequently described in greater detail, the TSVs 164 are small, such as smaller than the through vias 154. As a result of the TSVs 164 being small, they may have a greater density, thereby increasing the amount of connections to the interconnection dies 160.

In embodiments where the interconnection dies 160 are LSIs, the interconnection dies 160 may be bridge structures that include die bridges 168. The die bridges 168 may be metallization layers formed in and/or on, e.g., the substrate 162, and work to interconnect overlying integrated circuit devices (subsequently described) to one another. The die bridges 168 are located at the front-side of the interconnection dies 160. As such, the LSIs can be used to directly connect and allow communication between the integrated circuit devices. In such embodiments, the interconnection dies 160 can be placed in regions that are disposed between the subsequently attached integrated circuit devices, so that each interconnection die 160 overlaps multiple overlying integrated circuit devices. In some embodiments, the interconnection dies 160 may further include logic devices and/or memory devices. In some embodiments, the interconnection dies 160 may be free of logic devices and/or memory devices. The interconnection dies 160 are attached to the UBMLs 152 such that the die bridges 168 face away from the back-side redistribution structure 112.

In the illustrated embodiment, the interconnection dies 160 are attached to the back-side redistribution structure 112 (via the UBMLs 152) with solder bonds, such as with conductive connectors 170. The conductive connectors 170 may be ball grid array (BGA) connectors, solder balls, metal pillars, controlled collapse chip connection (C4) bumps, micro bumps, electroless nickel-electroless palladium-immersion gold technique (ENEPIG) formed bumps, or the like. The conductive connectors 170 may include a conductive material such as solder, copper, aluminum, gold, nickel, silver, palladium, tin, the like, or a combination thereof. In some embodiments, the conductive connectors 170 are formed by initially forming a layer of solder through evaporation, electroplating, printing, solder transfer, ball placement, or the like. Once a layer of solder has been formed, a reflow may be performed in order to shape the material into the desired bump shapes. Attaching the interconnection die 160 to the UBMLs 152 may include placing the interconnection die 160 on the UBMLs 152 (e.g., using a pick-and-place process) and reflowing the conductive connectors 170 to physically and electrically couple the die connectors 166 to the UBMLs 152. In another embodiment, the interconnection dies 160 are attached to the back-side redistribution structure 112 with direct bonds, using the die connectors 166.

In some embodiments, an underfill 172 is formed around the conductive connectors 170, and between the back-side redistribution structure 112 and the interconnection dies 160. The underfill 172 may reduce stress and protect the joints resulting from the reflowing of the conductive connectors 170. The underfill 172 may also be used to securely bond the interconnection dies 160 to the back-side redistribution structure 112 and provide structural support and environmental protection. The underfill 172 may be formed of a molding compound, epoxy, or the like. The underfill 172 may be formed by a capillary flow process after the interconnection dies 160 are attached, or may be formed by a suitable deposition method before the interconnection dies 160 are attached. The underfill 172 may be applied in liquid or semi-liquid form and then subsequently cured.

Optionally, the interconnection dies 160 may include die connectors 174 disposed at the front-side of the interconnection die 160. The die connectors 174 may be electrically coupled to the die bridges 168.

The interconnection dies 160 may be optional components in the wafer package. The inclusion or exclusion of interconnection dies 160 may depend on specific design requirements, performance goals, or manufacturing considerations. Additionally, while the interconnection dies 160 may be implemented as local silicon interconnects (LSIs) in some cases, alternative components such as integrated voltage regulators (IVRs) or integrated passive devices (IPDs) may be used in place of LSIs. These alternative components may provide different functionalities or advantages depending on the specific needs of the wafer package. For example, IVRs may offer improved power management capabilities, while IPDs may provide enhanced passive component integration within the wafer package.

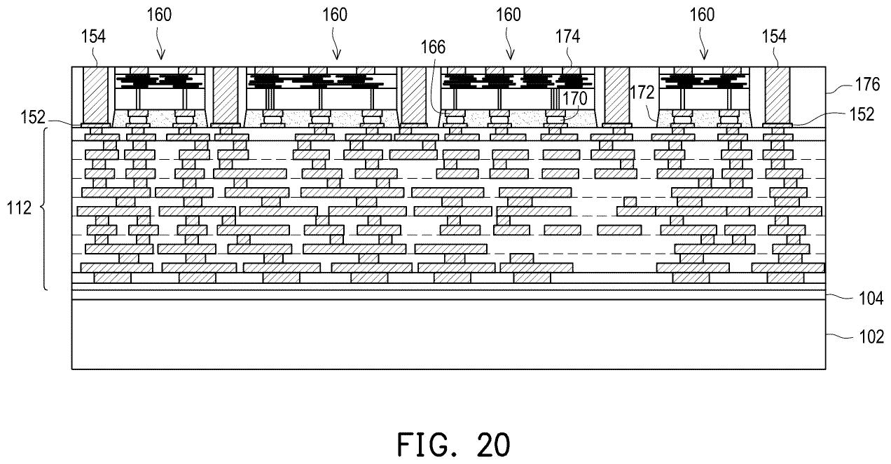

In FIG. 20, an encapsulant 176 is formed on and around the various components. After formation, the encapsulant 176 encapsulates the UBMLs 152, the through vias 154, the interconnection dies 160, and/or the underfill 172. The encapsulant 176 may be a molding compound, epoxy, or the like. The encapsulant 176 may be applied by compression molding, transfer molding, or the like, and may be formed over the carrier substrate 102 such that the through vias 154 and/or the interconnection dies 160 are buried or covered. The encapsulant 176 is further formed in gap regions between the interconnection dies 160 and the through vias 154. The encapsulant 176 may be applied in liquid or semi-liquid form and then subsequently cured.

A planarization process may optionally be performed on the encapsulant 176 to expose the through vias 154 and the interconnection dies 160 (e.g., the die connectors 174). The planarization process may remove material of the through vias 154, the interconnection dies 160, and/or the encapsulant 176 until the interconnection dies 160 and the through vias 154 are exposed. The upper surfaces of the through vias 154, the die connectors 174, and the encapsulant 176 are substantially coplanar (within process variations) after the planarization process. The planarization process may be, for example, a chemical-mechanical polish (CMP), a grinding process, or the like. In some embodiments, the planarization may be omitted, for example, if the through vias 154 and/or the die connectors 174 are already exposed. After the planarization process, the through vias 154 extend through the encapsulant 176. As such, the through vias 154 may be referred to as through-mold vias (TMVs).

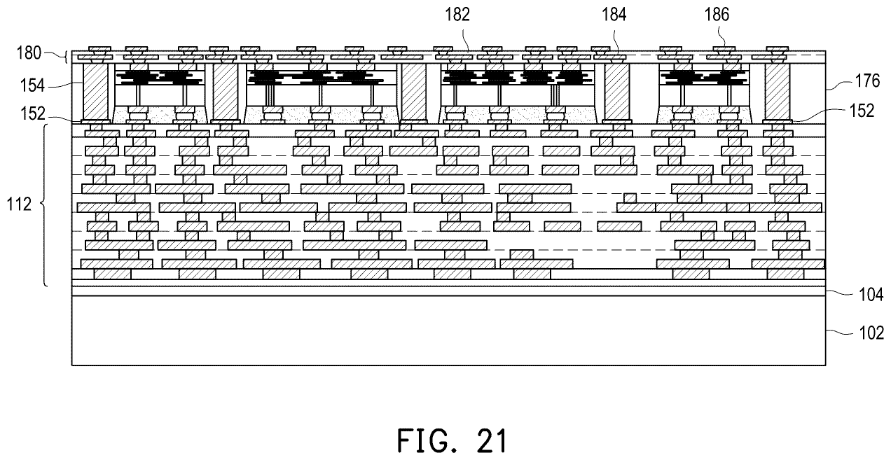

In FIG. 21, a front-side redistribution structure 180 is formed on the front-side surfaces of the encapsulant 176, the interconnection dies 160 (e.g., the die connectors 174), and the through vias 154. The front-side redistribution structure 180 includes dielectric layers 182 and metallization layer(s) 184 (sometimes referred to as redistribution layers or redistribution lines) among the dielectric layers 182. Thus, the front-side redistribution structure 180 includes metallization layer(s) 184 separated from each other by respective dielectric layers 182. The metallization layer(s) 184 of the front-side redistribution structure 180 are connected to the through vias 154 and to the interconnection dies 160 (e.g., the die connectors 174).

In some embodiments, the dielectric layers 182 are formed of a polymer, which may be a photosensitive material such as PBO, polyimide, a BCB-based polymer, or the like, that may be patterned using a lithography mask. In other embodiments, the dielectric layers 182 are formed of a nitride such as silicon nitride, an oxide such as silicon oxide, or the like. The dielectric layers 182 may be formed by spin coating, lamination, CVD, the like, or a combination thereof. After a dielectric layer 182 is formed, it may be patterned to expose underlying conductive features, such as portions of the through vias 154, the die connectors 174, and/or the metallization layer(s) 184. The patterning may be by any acceptable process, such as by exposing the dielectric layers 182 to light when they are formed of photosensitive material, or by etching using, for example, an anisotropic etch. If the dielectric layers 182 are formed of a photosensitive material, the dielectric layers 182 may be developed after the exposure.

The metallization layer(s) 184 each include conductive vias and/or conductive lines. The conductive vias extend through respective dielectric layers 182, and the conductive lines extend along respective dielectric layers 182. As an example to form a metallization layer 184, a seed layer (not separately illustrated) is formed over the respective underlying features. For example, the seed layer may be formed on a respective dielectric layer 182 and in any openings through the respective dielectric layer 182. In some embodiments, the seed layer includes a titanium layer and a copper layer over the titanium layer. The seed layer may be formed using a deposition process, such as PVD or the like. A photoresist is then formed and patterned on the seed layer. The photoresist may be formed by spin coating or the like and may be exposed to light for patterning. The pattern of the photoresist corresponds to the metallization layer 184. The patterning forms openings through the photoresist to expose the seed layer. A conductive material is formed in the openings of the photoresist and on the exposed portions of the seed layer. The conductive material may be formed by plating, such as electroless plating or electroplating from the seed layer, or the like. The conductive material may include a metal or a metal alloy, such as copper, titanium, tungsten, aluminum, the like, or combinations thereof. Then, the photoresist and portions of the seed layer on which the conductive material are not formed are removed. The photoresist may be removed by an acceptable ashing or stripping process, such as using an oxygen plasma or the like. Once the photoresist is removed, exposed portions of the seed layer are removed, such as by an acceptable etching process, such as by wet or dry etching. The remaining portions of the seed layer and conductive material form a metallization layer 184 of the front-side redistribution structure 180.

The front-side redistribution structure 180 is illustrated as an example. More or fewer dielectric layers 182 and metallization layer(s) 184 than illustrated may be formed by performing the previously described steps any desired quantity of times.

Under-bump metallizations (UBMs) 186 may be formed through the upper dielectric layer 182 of the front-side redistribution structure 180. The UBMs 186 are physically and electrically coupled to the upper metallization layer 184 of the front-side redistribution structure 180. The UBMs 186 each include conductive vias and conductive bumps. The conductive vias extend through the upper dielectric layer 182, and the conductive bumps extend along the upper dielectric layer 182. The UBMs 186 may be formed of the same material(s) as the metallization layer(s) 184. In some embodiments, the UBMs 186 have a different size than the metallization layer(s) 184.

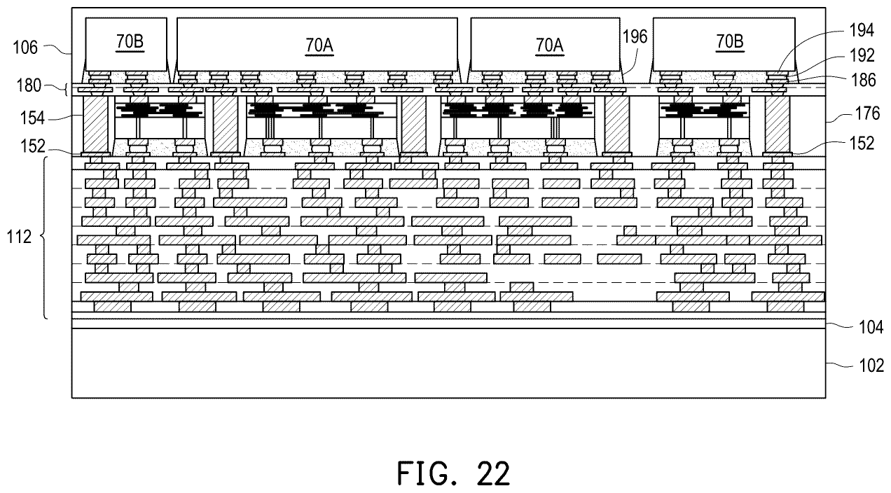

In FIG. 22, integrated circuit devices 70 are attached to the front-side redistribution structure 180. The integrated circuit devices 70 may be laid out in any of the aforementioned patterns and to a high density.

In the illustrated embodiment, the integrated circuit devices 70 are attached to the front-side redistribution structure 180 with solder bonds, such as with conductive connectors 192. The conductive connectors 192 may be formed of a conductive material that is reflowable, such as solder, copper, aluminum, gold, nickel, silver, palladium, tin, the like, or a combination thereof. In some embodiments, the conductive connectors 192 are formed by initially forming a layer of solder through methods such as evaporation, electroplating, printing, solder transfer, ball placement, or the like. Once a layer of solder has been formed, a reflow may be performed in order to shape the conductive connectors 192 into desired bump shapes. Attaching the integrated circuit devices 70 to the front-side redistribution structure 180 may include placing the integrated circuit devices 70 on the front-side redistribution structure 180 and reflowing the conductive connectors 192. The integrated circuit devices 70 may be placed on the front-side redistribution structure 180 using, e.g., a pick-and-place tool. The conductive connectors 192 are reflowed to attach die connectors 194 at the front-sides of the integrated circuit devices 70 to the UBMs 186 of the front-side redistribution structure 180, thereby electrically connecting the front-side redistribution structure 180 to the integrated circuit devices 70. In another embodiment, the integrated circuit devices 70 are attached to the front-side redistribution structure 180 with direct bonds, using the die connectors 194.

In some embodiments, an underfill 196 is formed around the conductive connectors 192, and between the front-side redistribution structure 180 and the integrated circuit devices 70. The underfill 196 may reduce stress and protect the joints resulting from the reflowing of the conductive connectors 192. The underfill 196 may be formed of an underfill material such as a molding compound, epoxy, or the like. The underfill 196 may be formed by a capillary flow process after the integrated circuit devices 70 are attached to the front-side redistribution structure 180, or may be formed by a suitable deposition method before the integrated circuit devices 70 are attached to the front-side redistribution structure 180. The underfill 196 may be applied in liquid or semi-liquid form and then subsequently cured.

An encapsulant 106 is formed around the various components. After formation, the encapsulant 106 laterally encapsulates the underfill 196 (if present) and the integrated circuit devices 70. The encapsulant 106 may be a molding compound, epoxy, or the like. The encapsulant 106 may be applied by compression molding, transfer molding, or the like, and may be formed over the front-side redistribution structure 180 such that the integrated circuit devices 70 are buried or covered. The encapsulant 106 is further formed in gap regions between the underfill 196 (if present) and/or the integrated circuit devices 70. The encapsulant 106 may be applied in liquid or semi-liquid form and then subsequently cured.

A removal process may optionally be performed on the encapsulant 106 to expose the integrated circuit devices 70. The removal process may include, for example, a planarization process such as a chemical-mechanical polish (CMP), a grinding process, or the like. The upper surfaces of the encapsulant 106 and the integrated circuit devices 70 may be substantially coplanar (within process variations) after the planarization process. The planarization may be omitted, for example, if the integrated circuit devices 70 are already exposed.

In FIG. 23, a carrier substrate de-bonding may be performed to detach (or “de-bond”) the carrier substrate 102 from the back-side redistribution structure 112. In accordance with some embodiments, the de-bonding includes projecting a light such as a UV light on the release layer 104 so that the release layer 104 decomposes under the heat of the light and the carrier substrate 102 can be removed. The remaining structure is a wafer package 100. The wafer package 100 may be placed on a tape, a carrier substrate, or another suitable support structure (not separately illustrated) for subsequent processing.

UBMs 140 may be formed for subsequent connection to the back-side redistribution structure 112. The UBMs 140 have bump portions on and extending along the major surface of the lower dielectric layer of the back-side redistribution structure 112, and have via portions extending through the lower dielectric layer of the back-side redistribution structure 112 to physically and electrically couple the lower metallization layer of the back-side redistribution structure 112. The UBMs 140 may be formed of the same material as the metallization layers, and may be formed by a similar process as the metallization layers. In some embodiments, the UBMs 140 may have a different size than the metallization layers.

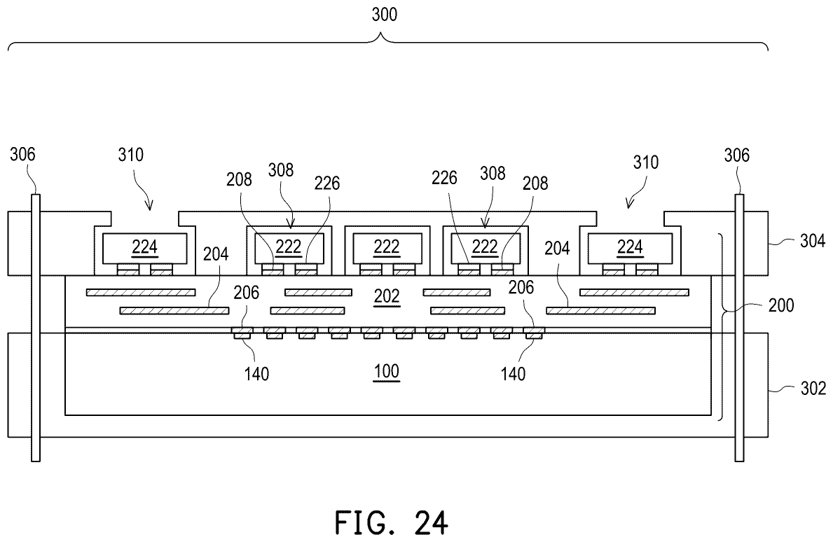

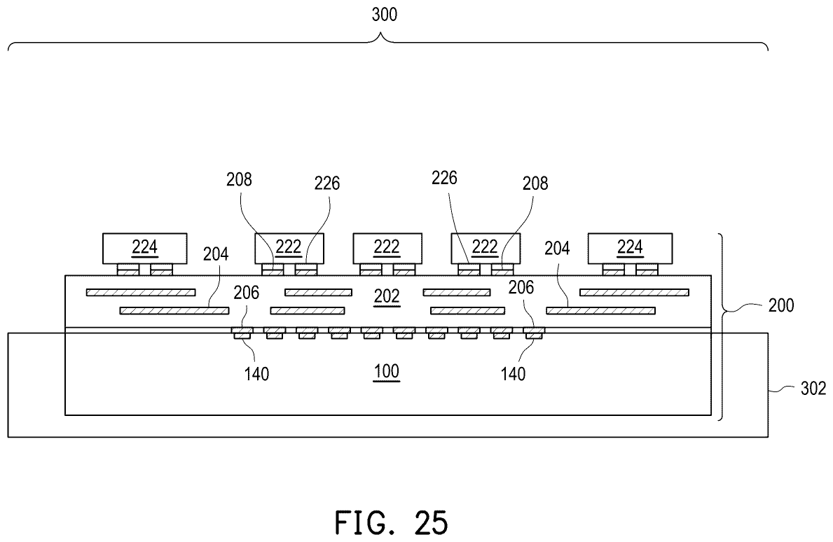

FIGS. 24-25 are cross-sectional views of system-on-wafer assemblies 300, in accordance with some other embodiments. These embodiments are similar to the embodiments of FIGS. 16-17, respectively, except the wafer package 100 is formed directly on the rigid interposer 202. That is, the back-side redistribution structure 112 may be built up over the rigid interposer 202 instead of a separate carrier substrate. As a result, the width of the rigid interposer 202 may be equal to (instead of greater than) the width of the wafer package 100.

In an embodiment, a device includes: an interposer; a package attached to a first side of the interposer, the package including an encapsulant and integrated circuit devices in the encapsulant; a plurality of passive devices attached to a second side of the interposer, the interposer electrically connecting the passive devices to the integrated circuit devices; and a plurality of first external connectors attached to the second side of the interposer, the interposer electrically connecting the first external connectors to the integrated circuit devices, the first external connectors disposed outside a perimeter of the package in the top-down view. In some embodiments, the device further includes: an adhesive film attaching the package to the interposer; and a plurality of reflowable connectors extending through the adhesive film, the reflowable connectors bonding conductive bumps of the package to conductive bumps of the interposer. In some embodiments, the device further includes: a plurality of second external connectors attached to the first side of the interposer, the second external connectors disposed outside the perimeter of the package in the top-down view. In some embodiments of the device, the second external connectors are optically connected to the integrated circuit devices by direct optical connections. In some embodiments of the device, the first external connectors are ribbon cable receptors and the passive devices are voltage regulators. In some embodiments of the device, the package is a truncated circular wafer and the interposer is a non-truncated circular wafer. In some embodiments of the device, respective ones of the passive devices overlap respective ones of the integrated circuit devices. In some embodiments, the device further includes: a cold plate attached to the first side of the interposer, the cold plate being in thermal contact with the package; a frame attached to the second side of the interposer, the frame having openings exposing the first external connectors; and a plurality of bolts extending through the cold plate and the frame. In some embodiments of the device, the package comprises more than eight of the integrated circuit devices, and each of the integrated circuit devices includes a system-on-chip die and a plurality of memory dies.

In an embodiment, a device includes: a cold plate; a frame including openings; and a system package between the cold plate and the frame, the system package including: an interposer; a wafer package attached to a first side of the interposer, a width of the interposer being greater than a width of the wafer package, the wafer package including an encapsulant and integrated circuit devices in the encapsulant; and a plurality of external connectors attached to a second side of the interposer, the interposer electrically connecting the external connectors to the integrated circuit devices, the openings of the frame exposing the external connectors. In some embodiments, the device further includes: a plurality of bolts extending through the cold plate and the frame. In some embodiments of the device, the wafer package is a truncated circular wafer and the interposer is a non-truncated circular wafer. In some embodiments of the device, the system package further includes: an adhesive film attaching the wafer package to the interposer. In some embodiments of the device, the external connectors are flexible printed circuit receptors.

In an embodiment, a method includes: attaching a package to a first side of an interposer, the package including an encapsulant and integrated circuit devices in the encapsulant; attaching a plurality of passive devices to a second side of the interposer, the interposer electrically connecting the passive devices to the integrated circuit devices, the passive devices disposed inside a perimeter of the package in a top-down view; and attaching a plurality of external connectors to the second side of the interposer, the interposer electrically connecting the external connectors to the integrated circuit devices, the external connectors disposed outside the perimeter of the package in the top-down view. In some embodiments of the method, attaching the package to the first side of the interposer includes: forming an adhesive film on the first side of the interposer; and pressing a dielectric layer of the package against the adhesive film. In some embodiments of the method, attaching the package to the first side of the interposer further includes: forming a plurality of reflowable connectors through the adhesive film;
and pressing conductive bumps of the package into the reflowable connectors while reflowing the reflowable connectors. In some embodiments of the method, attaching the passive devices to the second side of the interposer includes: aligning the passive devices with the integrated circuit devices in the top-down view. In some embodiments, the method further includes: placing the package on a cold plate; placing a frame on the interposer; and screwing the cold plate and the frame together. In some embodiments, the method further includes: placing the package and the interposer in a jig while attaching the passive devices and the external connectors to the second side of the interposer.

The foregoing outlines features of several embodiments so that those skilled in the art may better understand the aspects of the present disclosure. Those skilled in the art should appreciate that they may readily use the present disclosure as a basis for designing or modifying other processes and structures for carrying out the same purposes and/or achieving the same advantages of the embodiments introduced herein. Those skilled in the art should also realize that such equivalent constructions do not depart from the spirit and scope of the present disclosure, and that they may make various changes, substitutions, and alterations herein without departing from the spirit and scope of the present disclosure.

What is claimed is:

1. A device comprising:
an interposer;
a package attached to a first side of the interposer, the package comprising an encapsulant and a plurality of integrated circuit devices in the encapsulant;
a plurality of passive devices attached to a second side of the interposer, the interposer electrically connecting the passive devices to the integrated circuit devices; and
a plurality of first external connectors attached to the second side of the interposer, the interposer electrically connecting the first external connectors to the integrated circuit devices, the first external connectors disposed outside a perimeter of the package in a top-down view.

2. The device of claim 1, further comprising:
an adhesive film attaching the package to the interposer; and
a plurality of reflowable connectors extending through the adhesive film, the reflowable connectors bonding conductive bumps of the package to conductive bumps of the interposer.

3. The device of claim 1, further comprising:
a plurality of second external connectors attached to the first side of the interposer, the second external connectors disposed outside the perimeter of the package in the top-down view.

4. The device of claim 3, wherein the second external connectors are optically connected to the integrated circuit devices by direct optical connections.

5. The device of claim 1, wherein the first external connectors are ribbon cable receptors and the passive devices are voltage regulators.

6. The device of claim 1, wherein the package is a truncated circular wafer and the interposer is a non-truncated circular wafer.

7. The device of claim 1, wherein respective ones of the passive devices overlap respective ones of the integrated circuit devices.

8. The device of claim 1, further comprising:
a cold plate attached to the first side of the interposer, the cold plate being in thermal contact with the package;
a frame attached to the second side of the interposer, the frame having openings exposing the first external connectors; and
a plurality of bolts extending through the cold plate and the frame.

9. The device of claim 1, wherein the package comprises more than eight of the integrated circuit devices, and each of the integrated circuit devices comprises a system-on-chip die and a plurality of memory dies.

10. A device comprising:
a cold plate;
a frame comprising openings; and
a system package between the cold plate and the frame, the system package comprising:
an interposer;
a wafer package attached to a first side of the interposer, a width of the interposer being greater than a width of the wafer package, the wafer package comprising an encapsulant and a plurality of integrated circuit devices in the encapsulant; and
a plurality of external connectors attached to a second side of the interposer, the interposer electrically connecting the external connectors to the integrated circuit devices, the openings of the frame exposing the external connectors.

11. The device of claim 10, further comprising:
a plurality of bolts extending through the cold plate and the frame.

12. The device of claim 10, wherein the wafer package is a truncated circular wafer and the interposer is a non-truncated circular wafer.

13. The device of claim 10, wherein the system package further comprises:
an adhesive film attaching the wafer package to the interposer.

14. The device of claim 10, wherein the external connectors are flexible printed circuit receptors.

15. A method comprising:
attaching a package to a first side of an interposer, the package comprising an encapsulant and a plurality of integrated circuit devices in the encapsulant;
attaching a plurality of passive devices to a second side of the interposer, the interposer electrically connecting the passive devices to the integrated circuit devices, the passive devices disposed inside a perimeter of the package in a top-down view; and
attaching a plurality of external connectors to the second side of the interposer, the interposer electrically connecting the external connectors to the integrated circuit devices, the external connectors disposed outside the perimeter of the package in the top-down view.

16. The method of claim 15, wherein attaching the package to the first side of the interposer comprises:
forming an adhesive film on the first side of the interposer; and
pressing a dielectric layer of the package against the adhesive film.

17. The method of claim 16, wherein attaching the package to the first side of the interposer further comprises:
forming a plurality of reflowable connectors through the adhesive film; and
pressing conductive bumps of the package into the reflowable connectors while reflowing the reflowable connectors.

18. The method of claim 15, wherein attaching the passive devices to the second side of the interposer comprises:
aligning the passive devices with the integrated circuit devices in the top-down view.

19. The method of claim 15, further comprising:
placing the package on a cold plate;
placing a frame on the interposer; and
screwing the cold plate and the frame together.

20. The method of claim 15, further comprising:
placing the package and the interposer in a jig while attaching the passive devices and the external connectors to the second side of the interposer.
